(19) United States
(12) Patent Application Publication
(10) Pub. No.: US 2007/0001215 A1
(43) Pub. Date: Jan. 4, 2007

(54) Non-volatile memory device having a floating gate and method of forming the same

(75) Inventors: Jong-Kwang Llm, Suwon-si (KR); Jeong-Hyuk Choi, Seongnam-si (KR); Woon-Kyung Lee, Seongnam-si (KR); Jai-Hyuk Song, Sooul (KR)

Correspondence Address: F. CHAU & ASSOCIATES, LLC, 130 WOODBURY ROAD, WOODBURY, NY, 11797, US

(73) Assignee: Samsung Electronics Co., LTD.

(21) Appl. No.: 11/480,729

(22) Filed: Jul. 3, 2006

(30) Foreign Application Priority Data
Jul. 4, 2005 (KR) 2005-59783

(51) Int. Cl. H01L 29/788

(52) U.S. Cl. 257/315

(57) ABSTRACT

A nonvolatile memory device includes a device isolating layer disposed at a substrate to define an active region and a floating gate disposed on the active region. The floating gate includes a flat portion and a pair of wall portions. The pair of wall portions extend upward from both edges of the flat portion adjacent to the device isolating layer and face each other. The nonvolatile memory device further includes a tunnel insulating layer interposed between the floating gate and the active region. Moreover, the wall portions and the flat portion are formed of a single layer, and the thickness of the flat portion is larger than a width of the wall portions.

### CROSS-REFERENCE TO RELATED APPLICATION

This application claims priority from Korean Patent Application No. 10-2005-0059783, filed Jul. 4, 2005, the disclosure of which is hereby incorporated by reference in its entirety.

### BACKGROUND OF THE INVENTION

1. Technical Field

The present disclosure relates to a semiconductor device, and a method of forming the same, and more particularly, to a nonvolatile memory device having a floating gate and a method of forming the same.

2. Description of the Related Art

Non-volatile memory devices may retain their stored data even when their external power supply is interrupted. One such type of non-volatile memory device is a flash memory device which includes a floating gate for storing data. A flash memory cell can store logic ‘0’ and logic 1 by storing a charge in the floating gate or by emitting a charge from the floating gate. Moreover, a flash memory device having the floating gate is also capable of electrically writing and erasing data.

The floating gate in the flash memory cell can be formed on a semiconductor substrate with a gate oxide layer interposed therebetween. Charges can tunnel into the gate oxide layer by, for example, hot carrier injection or Fowler-Nordheim (F-N) tunneling. Conventionally, when an operating voltage is applied to the floating gate and an insulated control gate electrode, the flash memory cell can attain charge tunneling through the gate oxide layer by using the voltage difference between the voltage induced to the floating gate by the operating voltage and the voltage applied to the semiconductor substrate.

Furthermore, as high-integration and low power consumption are desireable for many semiconductor devices, research efforts have been made for enhancing the coupling ratio of flash memory cells. The coupling ratio may be defined as the ratio of the voltage induced to the floating gate to the operating voltage applied to a control gate electrode. In other words, as the coupling ratio increases, the voltage induced to the floating gate increases. Accordingly, the power consumption can be decreased by decreasing the operating voltage. One method for increasing the coupling ratio is to increase the static capacitance between the control gate electrode and the floating gate. However, due to the high integration of some semiconductor devices, it may be difficult in these devices to increase the static capacitance between the control gate electrode and the floating gate within such a limited area.

A flash memory cell may have, for example, a stack type gate structure in which a floating gate and a control gate electrode are stacked. With a flash memory cell having the above-mentioned stack type gate structure, one may sequentially etch an upper conductive layer for forming a control gate electrode, an intergate dielectric layer, and a lower conductive layer for forming a floating gate. However, some difficulties may be encountered with the above-mentioned sequential etching process, such as, for example, a semiconductor substrate disposed at both sides of a control gate may become damaged due to a large step height difference and/or an overetch, which thereby may result in an increase in the leakage current of the flash memory device.

Thus, there is a need for a nonvolatile memory device having an increased coupling ratio and in which possible damage to the semiconductor substrate disposed at both sides of the control gate may be minimized in comparison to conventional nonvolatile memory devices and to methods of forming the same.

### SUMMARY OF THE INVENTION

In accordance with an exemplary embodiment of the present invention provide, a nonvolatile memory device is provided. The nonvolatile memory device includes a device isolating layer formed at a substrate to define an active region and a floating gate disposed on the active region. The floating gate includes a flat portion and a pair of wall portions extending upward from both edges of the flat portion adjacent to the device isolating layer and facing each other. In addition, the nonvolatile memory device further includes a tunnel insulating layer is interposed between the floating gate and the active region. The wall portions and the flat portion are formed of a single layer, and the thickness of the flat portion is larger than the width of the wall portions.

The nonvolatile memory device may further include a control gate electrode disposed on the floating gate and crossing the active region and a blocking insulation pattern interposed between the control gate electrode and the floating gate. In this case, the wall portions include outer surfaces adjacent to the device isolating layer and inner surfaces facing the outer surfaces, and the control gate electrode covers an upper surface of the flat portion located between the pair of wall portions and the inner surfaces of the wall portions. An upper surface of the device isolating layer may be lower than upper surfaces of the wall portions. In this case, the control gate electrode may cover the outer surfaces of the wall portions located above the upper surface of the device isolating layer interposing the blocking insulation pattern. The edges of the flat portion adjacent to the device isolating layer may extend to cover edges of the device isolating layer.

The floating gate of the nonvolatile memory device may further include a buffer conductive pattern interposed between the flat portion and the tunnel insulating layer to be electrically connected to the flat portion. The lower surface of the flat portion may be larger than the upper surface of the buffer conductive pattern. The buffer conductive pattern may include a side aligned to a side of the flat portion. The nonvolatile memory device may further include an impurity-doped layer formed at the active region at both sides of the floating gate.

In accordance with an exemplary embodiment of the present invention, a method of forming a nonvolatile memory device is provided. The method includes forming a device isolating layer disposed at a substrate to define an active region and a tunnel insulating layer on the active region and forming a preliminary floating gate on the tunnel insulating layer. The preliminary floating gate includes a preliminary flat portion covering the active region and a pair of preliminary wall portions extending upward from both edges of the preliminary flat portion adjacent to the device isolating layer. The method further includes performing an isotropic etching process such that the thickness of the preliminary flat portion is larger than the width of the preliminary wall portions and forming a floating gate including a flat portion and a pair of wall portions extending upward from both edges of the flat portion by patterning the isotropically etched preliminary floating gate.

The method may further include forming a blocking insulating layer on the substrate and forming a control gate conductive layer on the blocking insulating layer. In this case, the patterning of the isotropically etched preliminary floating gate may include forming the floating gate, a blocking insulation pattern, and a control gate electrode by patterning the control gate conductive layer, the blocking insulating layer, and the isotropically etched preliminary floating gate.

In some exemplary embodiments, the isotropic etching process may be performed such that outer surfaces of the preliminary wall portions adjacent to the device isolating layer, inner surfaces of the preliminary wall portions facing the outer surfaces, and an upper surface of the preliminary flat portion located between the preliminary wall portions are exposed. In this case, an empty space surrounded by a protruding portion of the device isolating layer over the substrate is formed to expose the tunnel insulating layer, and a gate layer and a sacrificial layer are formed on the substrate. The preliminary flat portion, the preliminary wall portions, and a sacrifice pattern are formed in the empty space by planarizing the sacrificial layer and the gate layer until the device isolating layer is exposed. The inner surfaces of the preliminary wall portions and the upper surface of the preliminary flat portion between the preliminary wall portions are exposed by removing the sacrifice pattern. The outer surfaces of the preliminary wall portions are exposed by recessing the device isolating layer.

In other exemplary embodiments, the isotropic etching process may be performed such that outer surfaces of the preliminary wall portions adjacent to the device isolating layer are exposed, and inner surfaces of the preliminary wall portions facing the outer surfaces and an upper surface of the preliminary flat portion located between the preliminary wall portions are covered. In this case, an empty space surrounded by a protruding portion of the device isolating layer over the substrate is formed to expose the tunnel insulating layer, and a gate layer and a mold layer are formed on the substrate. The preliminary flat portion, the preliminary wall portions, and a mold pattern are formed in the empty space by planarizing the mold layer and the gate layer until the device isolating layer is exposed. The outer surfaces of the preliminary wall portions are exposed by recessing the device isolating layer. At this point, at least a portion of the mold pattern remains to cover the inner surfaces of the preliminary wall portions and the upper surface of the preliminary flat portion. In this case, the method may further include completely removing the mold pattern after the isotropic etching. The mold layer may include a stacked capping layer and a sacrificial layer. The capping layer may be formed of material having an etching selectivity to the device isolating layer while the sacrificial layer may be formed of the same material as the device isolating layer.

In yet other exemplary embodiments, the method may further include the forming of a preliminary buffer conductive pattern interposed between the tunnel insulating layer and the preliminary flat portion. In this case, the preliminary floating gate further includes the preliminary buffer conductive pattern, and the floating gate further includes a buffer conductive pattern formed by patterning the preliminary buffer conductive pattern.

### BRIEF DESCRIPTION OF THE DRAWINGS

Exemplary embodiments of the present invention can be understood in more detail from the following description taken in conjunction with the accompanying drawings, in which:

FIG. 1A is a plane view of a nonvolatile memory device according to an exemplary embodiment of the present invention;

FIGS. 1B and 1C are sectional views taken along the lines I-I′ and II-II′ of FIG. 1A, respectively;

FIGS. 2A to 7A are plane views for illustrating a method of forming a nonvolatile memory device according to an exemplary embodiment of the present invention;

FIGS. 2B to 7B are sectional views taken along the line III-III′ of FIGS. 2A to 7A respectively;

FIGS. 2C to 7C are sectional views taken along the line IV-IV′ of FIGS. 2A to 7A respectively;

FIGS. 8A to 11A are plane views for illustrating a modified example of a method of forming a nonvolatile memory device according to an exemplary embodiment of the present invention;

FIGS. 8B to 11B are sectional views taken along the line V-V′ of FIGS. 8A to 11A respectively;

FIGS. 8C to 11C are sectional views taken along the line VI-VI′ of FIGS. 8A to 11A respectively;

FIG. 12A is a plane view of a nonvolatile memory device according to an exemplary embodiment of the present invention;

FIGS. 12B and 12C are sectional views taken along the lines VII-VII′ and VIII-VIII′ of FIG. 12A respectively;

FIGS. 13A to 17A are sectional views taken along the line VII-VIII′ of FIG. 12A for illustrating a method of forming a nonvolatile memory device according to an exemplary embodiment of the present invention;

FIGS. 13B to 17B are sectional views taken along the line VIII-VIII′ of FIG. 12A for illustrating a method of forming a nonvolatile memory device according to an exemplary embodiment of the present invention;

FIGS. 18A to 20A are sectional views taken along of the line VII-VII′ FIG. 12A for illustrating a modified example of a method of forming a nonvolatile memory device according to an exemplary embodiment of the present invention; and

FIGS. 18B to 20B are sectional views taken along of the line VII-VIII′ FIG. 12A for illustrating a modified example of a method of forming a nonvolatile memory device according to an exemplary embodiment of the present invention.

### DETAILED DESCRIPTION OF THE EXEMPLARY EMBODIMENTS

The present invention will now be described more fully with reference to the accompanying drawings, in which exemplary embodiments of the invention are shown. The invention may, however, be embodied in many different forms and should not be construed as being limited to the exemplary embodiments set forth herein; It will also be understood that when a layer is referred to as being “on” another layer or substrate, it can be directly on the other layer or substrate, or intervening layers may also be present. Like reference numerals in the drawings denote like elements, and thus their description will be omitted.

### First Exemplary Embodiment

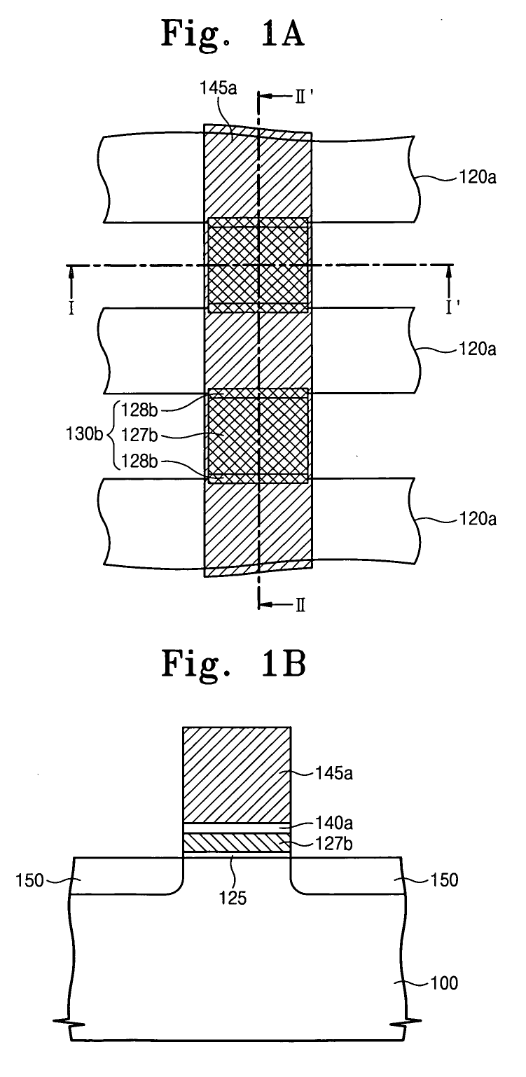

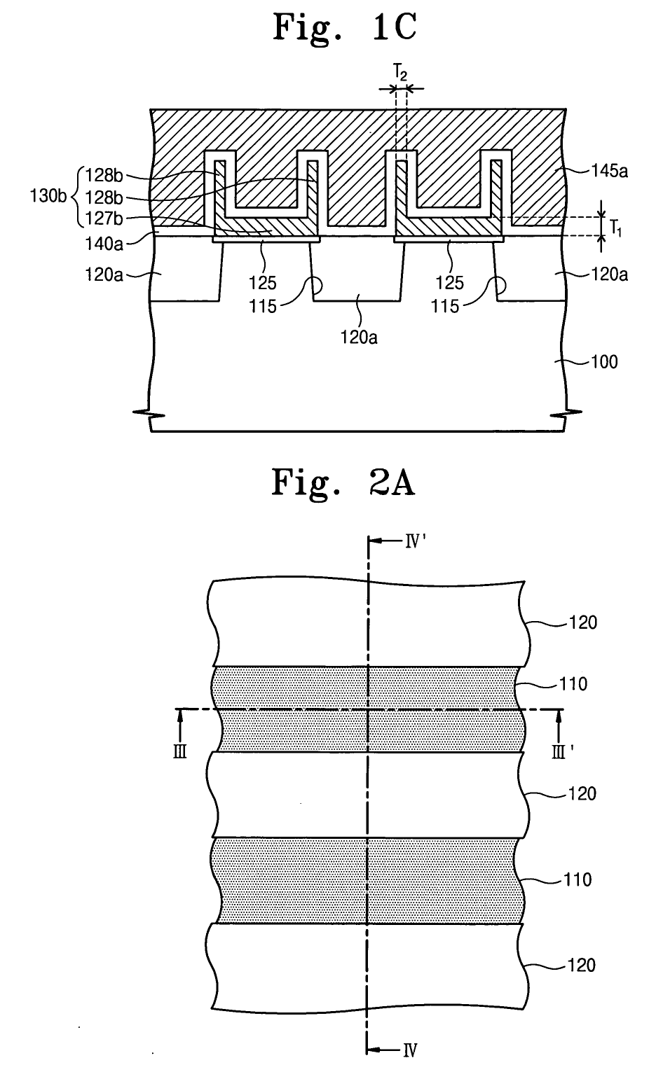

FIG. 1A is a plane view of a nonvolatile memory device according to an exemplary embodiment of the present invention, and FIGS. 1B and 1C are sectional views taken along the lines I-I′ and II-II′ of FIG. 1A, respectively.

Referring to FIGS. 1A, 1B, and IC, a device isolating layer 120a is disposed at a semiconductor substrate 100 (hereinafter, referred to as a substrate) to define an active region. A floating gate 130b is disposed on the active region, and a tunnel insulating layer 125 is interposed between the floating gate 130b and the active region. The floating gate 130b includes a flat portion 127b and a pair of wall portions 128b extending upward from both edges of the flat portion 127b and which face each other. Here, the tunnel layer 125 is interposed between the active region and the flat portion 127b. A thickness T1 of the flat portion 127b may be, for example, larger than a width T2 of the wall portions 128b. The flat portion 127b and the wall portions 128b may be formed, for example, of a single layer. That is, the flat portion 127b and the wall portions 128b are a single layer and connected to each other.

The wall portions 128b, may have, for example, a fin shape. The wall portions 128b may, for example, extend upward from the edges of the flat portion 127b adjacent to the device isolating layer 120a. The wall portions 128b have outer surfaces adjacent to the device isolating layer 120a and inner surfaces facing the outer surfaces. The edges of the flat portion 127b adjacent to the device isolating layer 120a may extend laterally to cover a portion of the device isolating layer 120a. In this case, the wall portions 128b extend upward from the extending edges of the flat portion 127b.

An impurity-doped layer 150 is disposed at the active region at both sides of the floating gate 130b. The impurity-doped layer 150 corresponds to a source/drain region of a nonvolatile memory cell.

A control gate electrode 145a is disposed on the floating gate 130b, and a blocking insulation pattern 140a is interposed between the control gate electrode 145a and the floating gate 130b. The control gate electrode 145a runs across the active region. The blocking insulation pattern 140a covers an upper surface of the flat portion 127b and the inner surfaces of the wall portions 128b. For example, the blocking insulation pattern 140a may cover the outer surfaces of the wall portions 128b. The blocking insulation pattern 140a may cover most of the outer surfaces of the wall portions 128b. At this point, an upper surface of the device isolating layer 120a is lower than an uppermost surface of the wall portions 128b. The upper surface of the device isolating layer 120a has a height such that the upper surface of the device isolating layer 120a is close to the lower surface of the flat portion 127b. The device isolating layer 120a may cover a side of the tunnel insulating layer 125.

The control gate electrode 145a covers the inner surfaces of the wall portions 128b and the upper surface of the flat portion 127b located between the wall portions 128b while interposing the blocking insulation pattern 140a. The control gate electrode 145a may fill a space surrounded by the pair of wall portions 128b and the flat portion 127b. Also, the control gate electrode 145a covers the outer surfaces of the wall portions 128b interposing the blocking insulation pattern 140a. A portion of the space adjacent to the impurity-doped layer 150 is open. For example, in the space, an upper portion and the portions adjacent to the impurity-doped layer 150 are open. A side of the flat portion 127b adjacent to the impurity-doped layer 150, a side of the blocking insulation pattern 140a, and a side of the control gate electrode 145a are aligned with one another. The impurity-doped layer 150 is disposed at both sides of the floating gate 130b and the control gate electrode 145a.

The device isolating layer 120a may be formed, for example, of a silicon oxide layer by chemical vapor deposition. The tunnel insulating layer 125 may be formed of a silicon oxide layer, such as, for example, a thermal oxidation layer. The flat portion 127b and the wall portions 128b may be formed of, for example, doped polysilicon. The blocking insulation pattern 140a may be formed of, for example, an oxide-nitride-oxide layer. Alternatively, the blocking insulation pattern 140a may include a high dielectric layer having a higher dielectric constant than the tunnel insulating layer 125. For example, the blocking insulation pattern 140a may include an insulating metal oxide such as hafnium oxide or aluminum oxide.

In the nonvolatile memory device of the present exemplary embodiment, the floating gate 130b includes the flat portion 127b and the wall portions 128b extending upward from both edges of the flat portion 127b. Accordingly, as the surface area of the floating gate 130b increases within the limited area, an overlapping area of the floating gate 130b and the control gate electrode 145a also increases. As a result, the coupling ratio of the nonvolatile memory cell increases, thereby decreasing the operating voltage of the nonvolatile memory device. In addition, by decreasing the operating voltage, the power consumption of the nonvolatile memory device may also be decreased, thereby providing a highly integrated memory device.

Also, the thickness T1 of the flat portion 127b of the floating gate 130b is thicker than the width T2 of the wall portions 128b. Therefore, the flat portion 127b has a sufficient thickness such that it can protect the active region at both sides of the floating gate 130b from an etching process for forming the control gate electrode 145a, the blocking insulation pattern 140a, and the floating gate 130b. That is, the flat portion 127b having a sufficient thickness can protect the active region at both sides of the floating gate 130b during the etching process. Therefore, etching damage may be minimized in the active region at both sides of the floating gate 130b, thereby improving the leakage current characteristic of the nonvolatile memory device.

In addition, as the width of the wall portions 128b is small, the distance between the pair of wall portions 128b and/or the distance between the adjacent floating gates 130b interposing the device isolating layers 120a may increase. Accordingly, the aspect ratio of the space surrounded by the pair of wall portions 128b and/or the aspect ratio of a space between the adjacent floating gates 130b can be decreased. As a result, voids and the like can be prevented from being generated in the control gate electrode 145a, thereby preventing the nonvolatile memory device from being degenerated.

A method of forming a nonvolatile memory device according an exemplary embodiment of the present invention will now be described with reference to drawings.

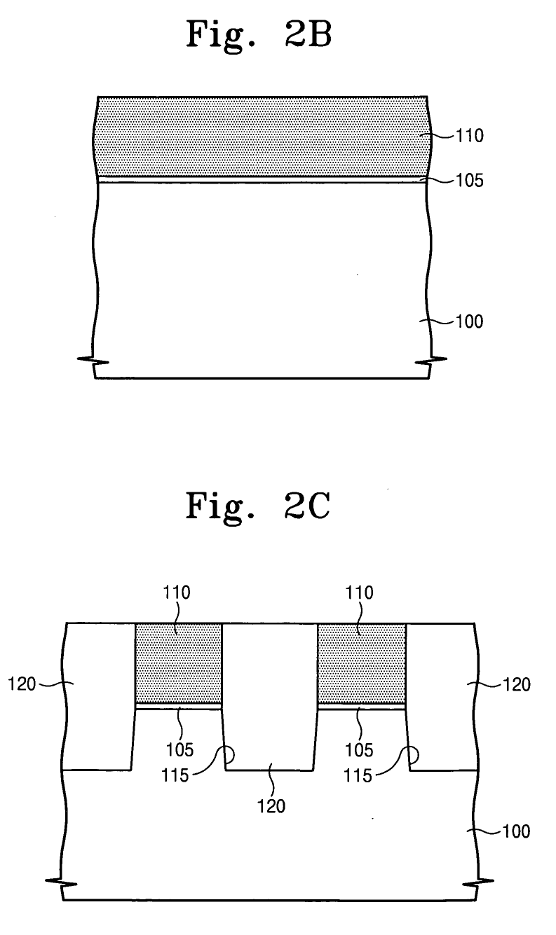

FIGS. 2A to 7A are plane views for illustrating the method of forming the nonvolatile memory device according to an exemplary embodiment of the present invention, FIGS. 2B to 7B are sectional views taken along the line III-III′ of FIGS. 2A to 7A respectively, and FIGS. 2C to 7C are sectional views taken along the line IV-IV′ of FIGS. 2A to 7A respectively.

Referring to FIGS. 2A, 2B, and 2C, a buffer insulating pattern 105 and a hard mask pattern 110 are sequentially stacked on a predetermined region of a substrate 100. Trenches 115 are formed to define an active region by etching the substrate 100 using the hard mask pattern 110 as a mask. The hard mask pattern 110 may be formed of material having an etching selectivity to the substrate 100, for example, nitride silicon. The buffer insulating pattern 105 may buff stress between the hard mask pattern 10 and the substrate 100. For example, the buffer insulating pattern 105 may be formed of a silicon oxide layer.

An insulating layer is formed on the whole surface of the substrate 100 to fill the trenches 115, and is planarized until the hard mask pattern 110 is exposed, thereby forming a device isolating layer 120. The device isolating layer 120 may be formed of, for example, a silicon oxide layer, by a high density plasma chemical vapor deposition (HDPCVD) process to have improved gap-fillproperties.

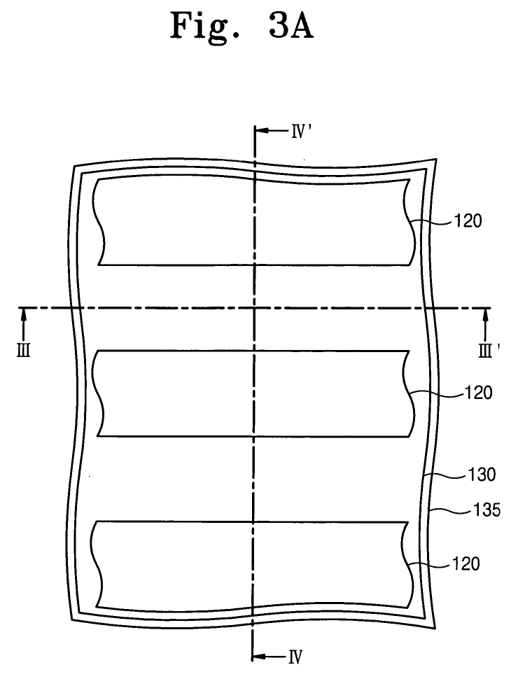

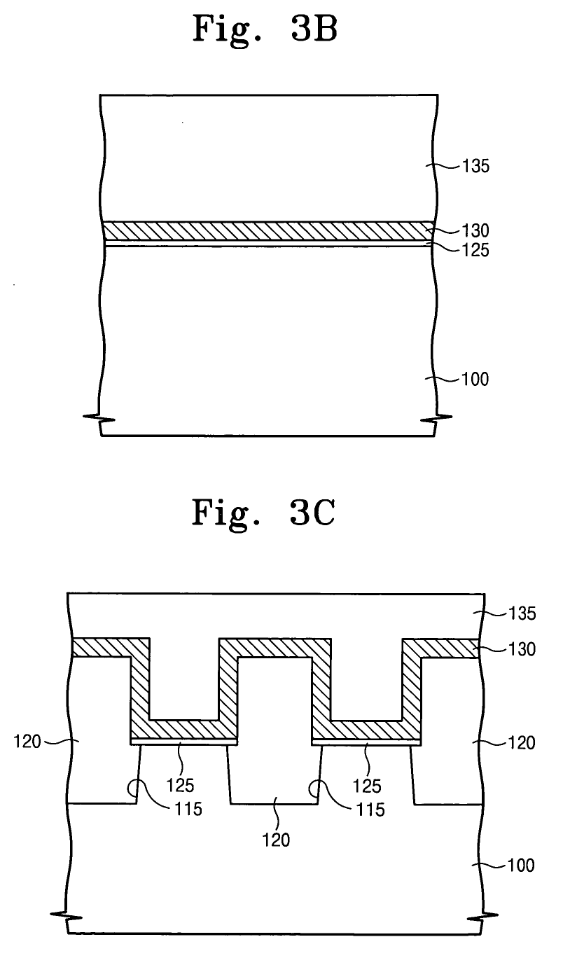

Referring to FIGS. 3A, 3B, and 3C, the buffer insulating pattern 105 is exposed by removing the exposed hard mask pattern 110 and the active region is exposed by removing the exposed buffer insulating pattern 105. An empty space surrounded by a protruding portion of the device isolating layer 120 over the substrate 100 is formed by removing the hard mask pattern 110 and the buffer insulating pattern 105. The hard mask pattern 110 may be removed by, for example, an isotropic etching process or an anisotropic etching process. The buffer insulating pattern 105 is removed, for example, by a wet etching process corresponding to an isotropic etching process. Therefore, plasma damage can be prevented on a surface of the exposed active region. When the buffer insulating pattern 105 is isotropically etched, the protruding portion of the device isolating layer 120 may be also etched, and thus the width of the empty space may become larger than the width of the active region.

A tunnel insulating layer 125 is formed on the exposed active region. The tunnel insulating layer 125 may be formed of a silicon oxide layer, particularly a thermal oxidation layer. A gate layer 130 is formed on the entire surface of the substrate 100. The gate layer 130 may be formed of, for example, doped polysilicon. The gate layer 130 may be formed with the same thickness on both sidewall portions of the empty space and the tunnel insulating layer 125.

A sacrificial layer 135 is formed on the gate layer 130 to fill the empty space. The sacrificial layer 135 may be formed of, for example, a silicon oxide layer or a silicon nitride layer.

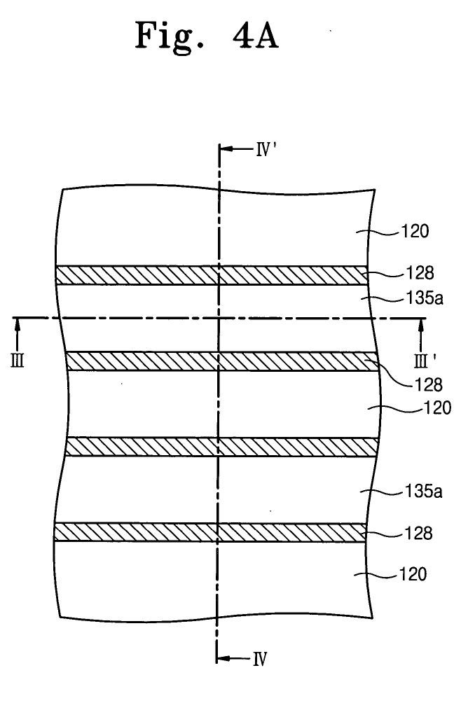

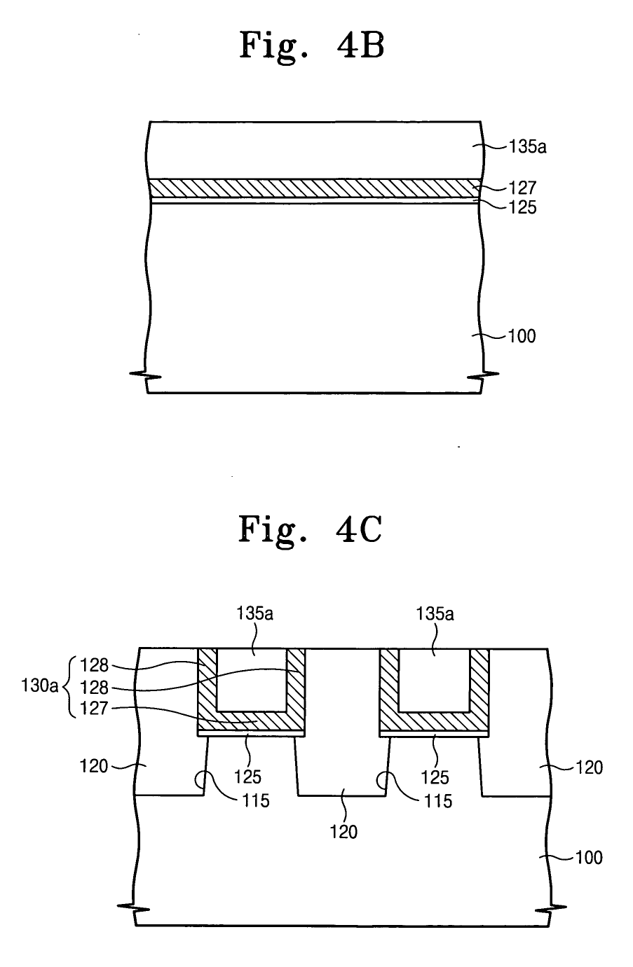

Referring to FIGS. 4A, 4B, and 4C, the sacrificial layer 135 and the gate layer 130 are planarized until an upper surface of the device isolating layer 120 is exposed to form a preliminary floating gate 130a and a sacrifice pattern 135a sequentially stacked in the empty space.

The preliminary floating gate 130a includes a preliminary flat portion 127 and a pair of preliminary wall portions 128 extending upward from both edges of the preliminary flat portion 127. The preliminary wall portions 128 extend upward along the sidewall portions of the empty space. That is, the preliminary wall portions 128 extend upward from the edges of the preliminary flat portion 127, adjacent to the device isolating layer 120. The preliminary flat portion 127 corresponds to a portion of the gate layer 130 formed on the tunnel insulating layer 125, and the preliminary wall portions 128 correspond to portions of the gate layer 130 formed on the sidewall portions of the empty space. The preliminary wall portions 128 have outer surfaces that are adjacent to the device isolating layer 120 and inner surfaces that are adjacent to the sacrifice pattern 135 and which face the outer surfaces. The thickness of the preliminary flat portion 127 may be the same as the width of the preliminary wall portions 128, like the gate layer 130.

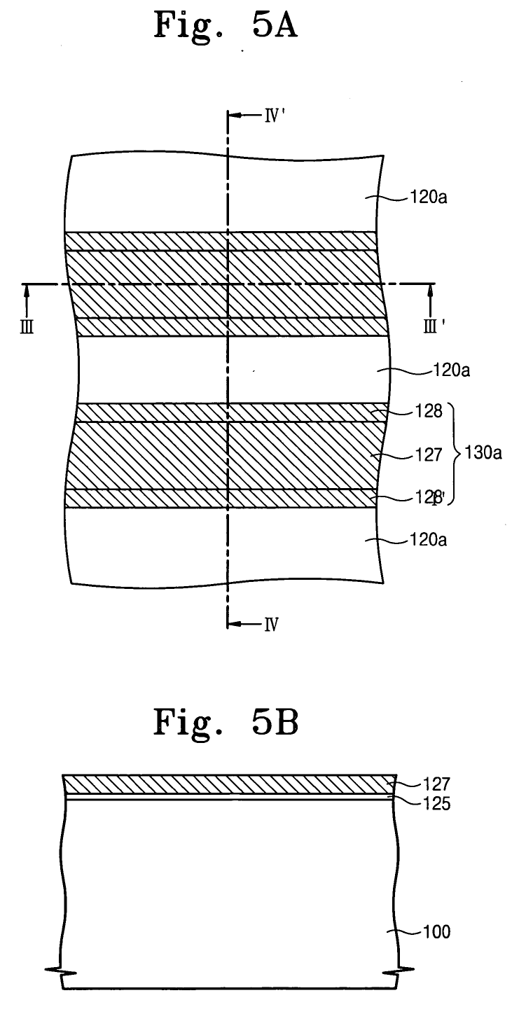

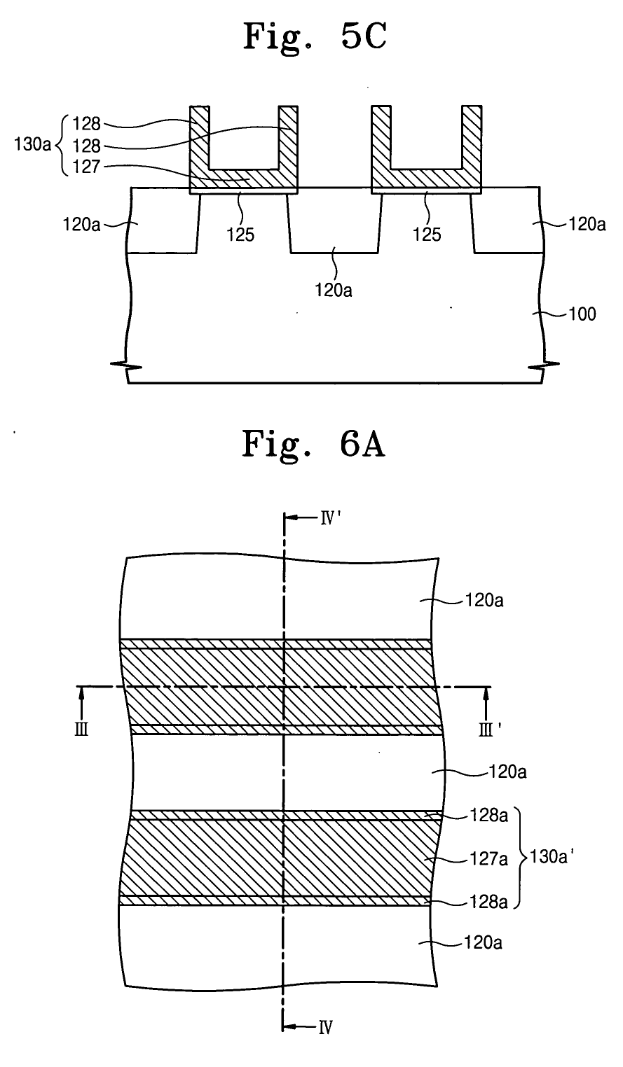

Referring to FIGS. 5A, 5B, and 5C, the sacrifice pattern 135a is removed to expose inner surfaces of the preliminary wall portions 128 and the upper surface of the preliminary flat portion 127 between the preliminary wall portions 128. The device isolating layer 120 is recessed to expose outer surfaces of the preliminary wall portions 128. At this point, the lower surface of the preliminary flat portion 127 contacts the tunnel insulating layer 125, and thus is not exposed. The upper surface of the recessed device isolating layer 120a may be formed with a height such that the upper surface of the recesses device isolating layer 120a is close to the lower surface of the preliminary flat portion 127. The recessed device isolating layer 120a may cover a side of the tunnel insulating layer 125.

As described above, the device isolating layer 120 may be recessed after removing the sacrifice pattern 135a or the sacrifice pattern 135a may be removed after recessing the device isolating layer 120. Alternatively, when both sacrifice pattern 135a and device isolating layer 120 are formed of a silicon oxide layer, the removing process of the sacrifice pattern 135a may be performed at the same time as the recessing process of the device isolating layer 120.

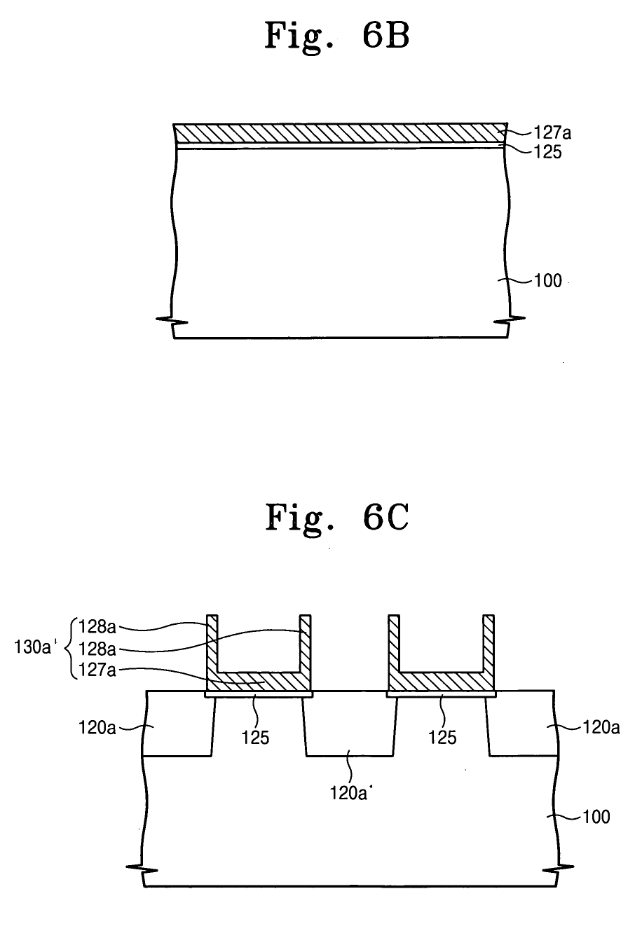

Referring to FIGS. 6A, 6B, and 6C, the exposed preliminary floating gate 130a is isotropically etched. The thickness of an isotropically etched preliminary flat portion 127a is larger than the width of isotropically etched preliminary wall portions 128a.

In the isotropic etching process of the present exemplary embodiment, an upper surface of the preliminary flat portion 127a is exposed, while the lower surface of the preliminary flat portion 127a is not exposed. On the other hand, both outer and inner surfaces of the preliminary wall portions 128a are exposed. Accordingly, the preliminary flat portion 127a is recessed through its upper surface, while the preliminary wall portions 128a are recessed through both inner and outer surfaces by the isotropic etching. As a result, the thickness of the isotropically etched preliminary flat portion 127a is larger than the width of the isotropically etched preliminary wall portions 128a.

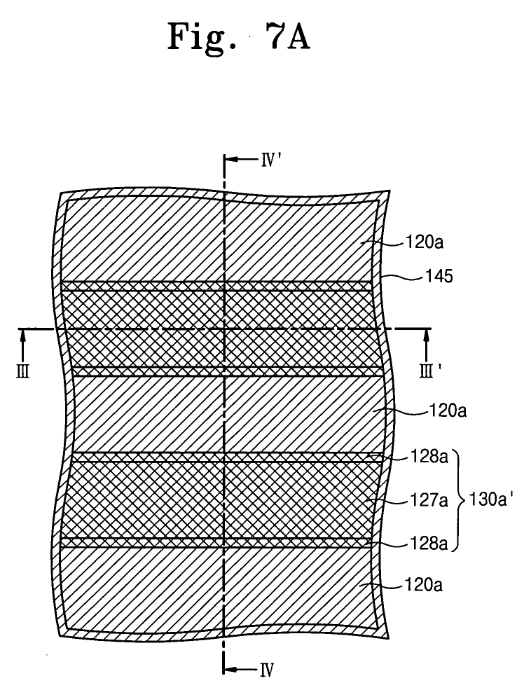

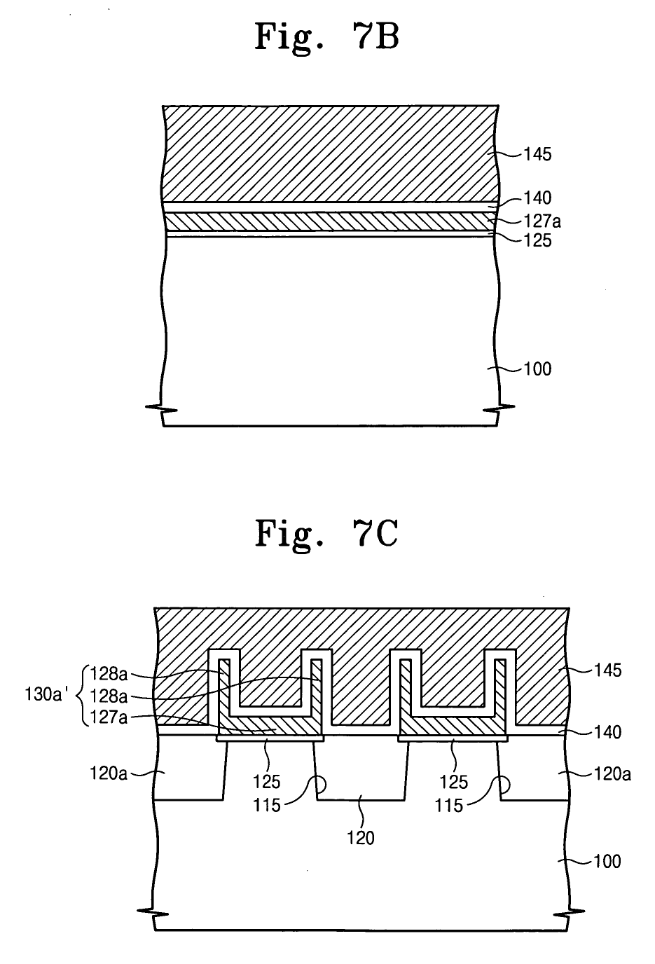

Referring to FIGS. 7A, 7B, and 7C, a blocking insulating layer 140 is formed on the substrate having the isotropically etched preliminary floating gate 130a′, and a control gate conductive layer 145 is formed on the blocking insulating layer 140. The blocking insulating layer 140 may be formed of, for example, an oxide-nitride-oxide layer. Alternatively, the blocking insulating layer 140 may include a high dielectric layer having a higher dielectric constant than the tunnel insulating layer 125. For example, the blocking insulating layer 140 may include an insulating metal oxide layer such as a hafnium oxide layer or an aluminum oxide layer. The control gate conductive layer 145 may be formed of a single layer of, for example, a doped polysilicon layer, a metal layer (e.g., a tungsten layer or a molybdenum layer), a conductive metal nitride layer (e.g., a titanium nitride layer or a tantalum nitride layer,), and a metal silicide layer (e.g., a tungsten silicide layer, a cobalt silicide layer, a nickel silicide layer, or a titanium silicide layer) or a multilayer of the aforementioned layers.

The floating gate 130b, the blocking insulation pattern 140a, and the control gate electrode 145a are formed, as illustrated in FIGS. 1A, 1B, and 1C, by sequentially patterning the control gate conductive layer 145, the blocking insulating layer 140, and the isotropically etched preliminary floating gate 130a′. The flat portion 127b and the wall portions 128b of the floating gate 130b are respectively formed from the isotropically etched preliminary flat portion 127a and the isotropically etched preliminary wall portions 128a.

The impurity-doped layer 150 illustrated in FIG. 1B is formed by injecting impurity ions using the control gate electrode 145a as a mask. Therefore, the nonvolatile memory device can be formed as illustrated FIGS. 1A, 1B, and 1C.

According to the method of forming the nonvolatile memory device of the present exemplary embodiments, the floating gate 130b includes the flat portion 127b and the pair of wall portions 128b extending upward from both edges of the flat portion 127b. Accordingly, the overlapping area of the floating gate 130b and the control gate electrode 145a increases, and thus the coupling ratio of the nonvolatile memory cell also increases. As a result, a nonvolatile memory device with low power consumption and a high integration may be obtained.

Also, the width of the isotropically etched preliminary wall portions 128a is smaller than the thickness of the preliminary flat portion 127a, thereby decreasing the aspect ratio of a first space between the pair of preliminary wall portions 128a and/or the aspect ratio of a second space between the adjacent preliminary floating gates 130a′ interposing the device isolating layer 120a. Accordingly, the control gate conductive layer 145 may be readily formed in the first and second spaces, thereby preventing voids from being generated in the first and second spaces.

In addition, in the etching process of the patterning process for forming the control gate electrode 145a, the blocking insulation pattern 140a, and the floating gate 130b, the thickness of the preliminary flat portion 127a of the preliminary floating gate 130a′ is larger than the width of the preliminary wall portions 128a. That is, the preliminary flat portion 127a has a thickness such that the active region at both sides of the control gate electrode 145a can be protected during the etching process of the patterning process. As a result, etching damage to the active region at both sides of the control gate electrode 145a is minimized, thereby improving the leakage current characteristic of the nonvolatile memory device.

Meanwhile, the thickness of a preliminary flat portion may be formed larger than the width of preliminary wall portions through a modified example of a method in accordance with an exemplary embodiment of the present invention. The modified example will now be described with reference to drawings.

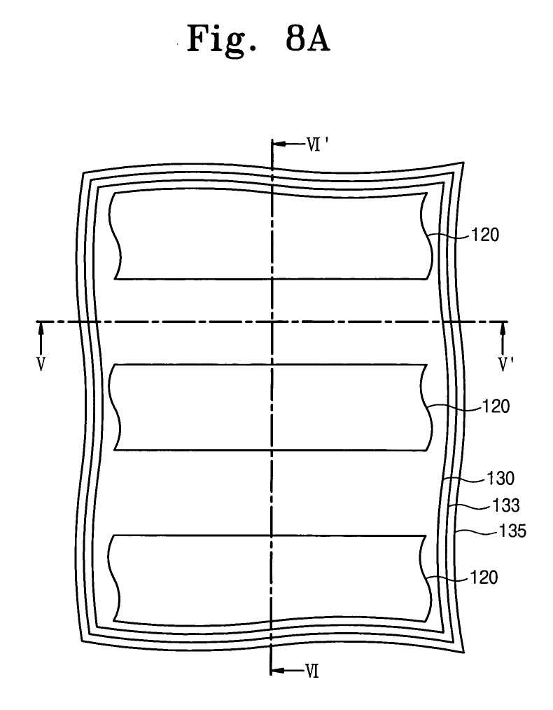

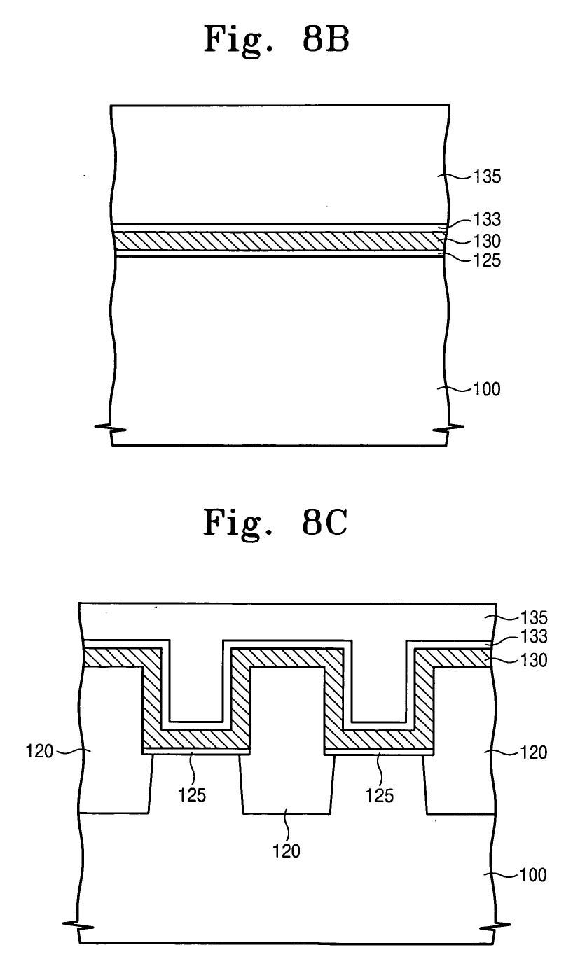

FIGS. 8A to 11A are plane views for illustrating a modified example of a method of forming a nonvolatile memory device according to an exemplary embodiment of the present invention, FIGS. 8B to 11B are sectional views taken along the line V-V′ of FIGS. 8A to 11A respectively, and FIGS. 8C to 11C are sectional views taken along the line VI-VI′ of FIGS. 8A to 11A respectively.

Referring to FIGS. 8A, 8B, and 8C, a tunnel insulating layer 125 and a gate layer 130 may be formed in an empty space surrounded by a protruding portion of a device isolating layer 120 using the same method as the method described with reference to FIGS. 2A, 2B, 2C, 3A, 3B, and 3C.

A mold layer is formed on the gate layer 130. The mold layer includes material having an etching selectivity to the device isolating layer 120. For example, the mold layer may include sequentially stacked capping layer 133 and sacrificial layer 135. In this case, the capping layer 133 may be formed of material having an etching selectivity to the device isolating layer 120. In addition, the sacrificial layer 135 may be formed of the same material as the device isolating layer 120. For example, the capping layer 133 may be formed of a silicon nitride layer or a silicon oxide nitride layer, and the device isolating layer 120 and the sacrificial layer 135 may be formed of a silicon oxide layer. Alternatively, the sacrificial layer 135 may be formed of, for example, a silicon nitride layer. That is, the whole mold layer may be formed of material having an etching selectivity to the device isolating layer 120.

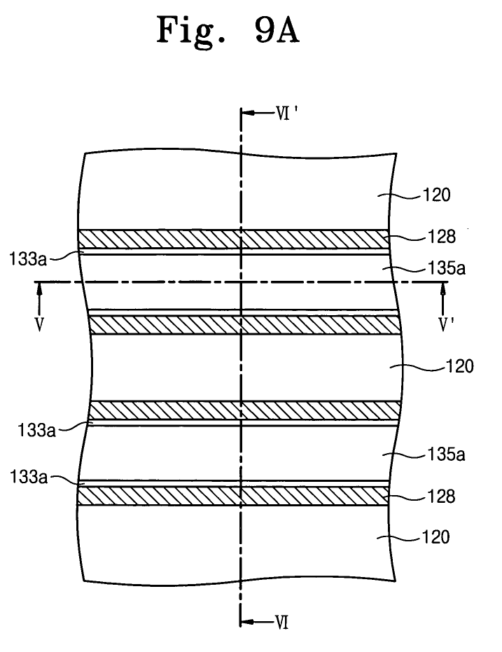

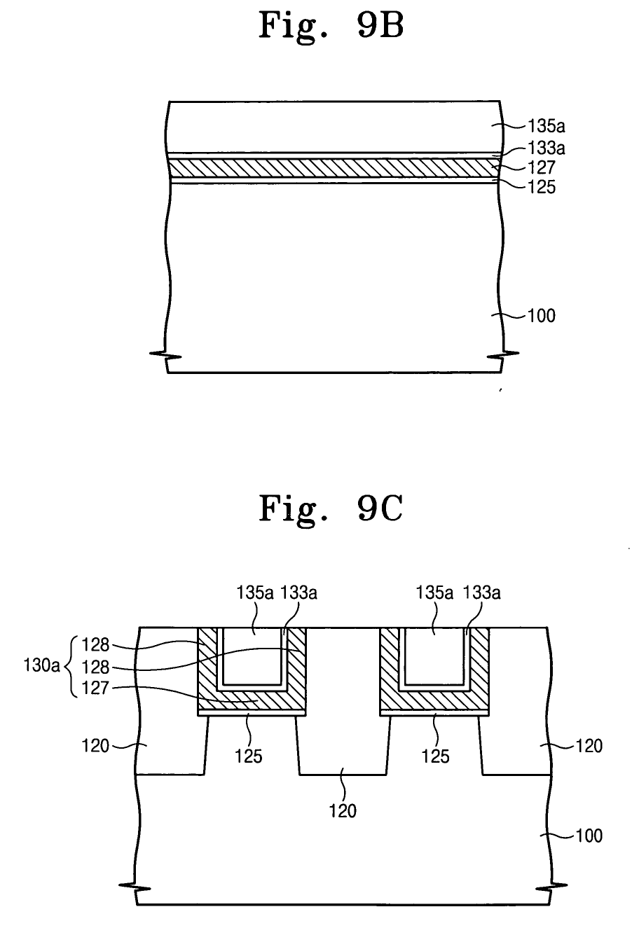

Referring to FIGS. 9A, 9B, and 9C, the mold layer and the gate layer 130 are planarized until the device isolating layer 120 is exposed to form a preliminary floating gate 130a and a mold pattern sequentially stacked in the empty space. The preliminary floating gate 130a includes a preliminary flat portion 127 and a pair of preliminary wall portions 128 extending upward from both edges of the preliminary flat portion 127. The mold pattern may include sequentially stacked capping pattern 133a and sacrifice pattern 135a.

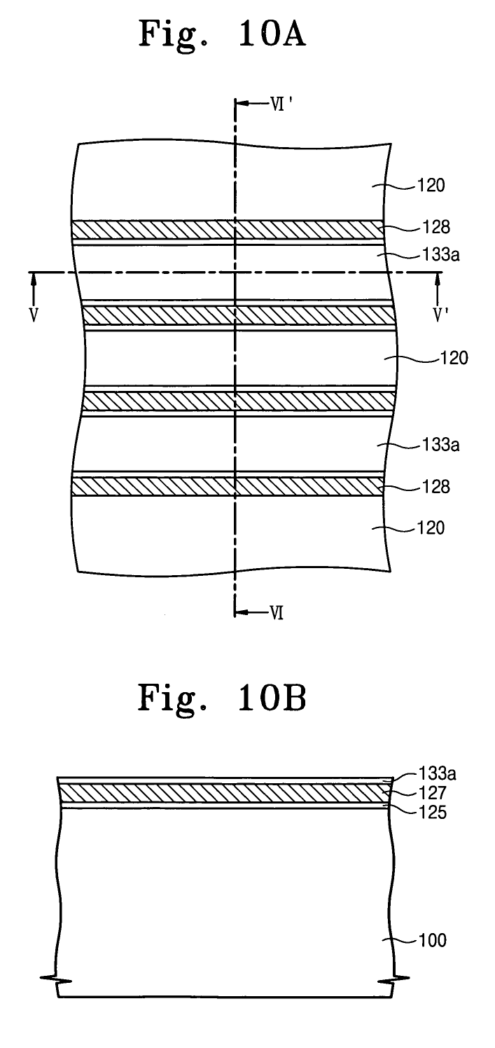

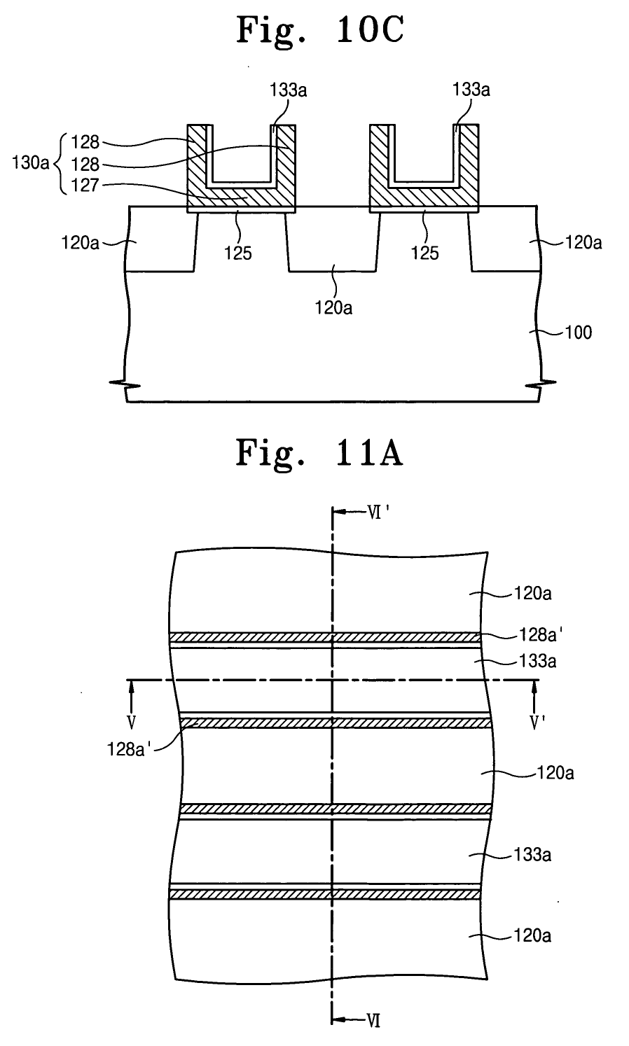

Referring to FIGS. 10A, 10B, and 10C, the device isolating layer 120 is recessed to expose outer surfaces of the preliminary wall portions 128. At this point, at least a portion of the mold pattern remains to cover inner surfaces of the preliminary wall portions 128 and the upper surface of the preliminary flat portion 127 between the preliminary wall portions 128. That is, the inner surfaces of the preliminary wall portions 128 and the upper surface of the preliminary flat portion 127 are not exposed. Also, the lower surface of the preliminary flat portion 127 contacts the tunnel insulating layer 125, and thus is not exposed. The upper surface of the recessed device isolating layer 120a may have a height such that the upper surface of the recessed device isolating layer 120a is close to the lower surface of the preliminary flat portion 127.

When the sacrifice pattern 135a is formed of the same material as the device isolating layer 120, the sacrifice pattern 135a may be removed during recessing of the device isolating layer 120. However, the capping pattern 133a has an etching selectivity to the device isolating layer 120, and thus remains to cover the inner surfaces of the preliminary wall portions 128 and the upper surface of the preliminary flat portion 127.

On the other hand, when the sacrifice pattern 135a is formed of material having an etching selectivity to the device isolating layer 120 (that is, the whole mold pattern is formed of material having an etching selectivity to the device isolating layer 120), most of the mold pattern remains to cover the inner surfaces of the preliminary wall portions 128 and the upper surface of the preliminary flat portion 127.

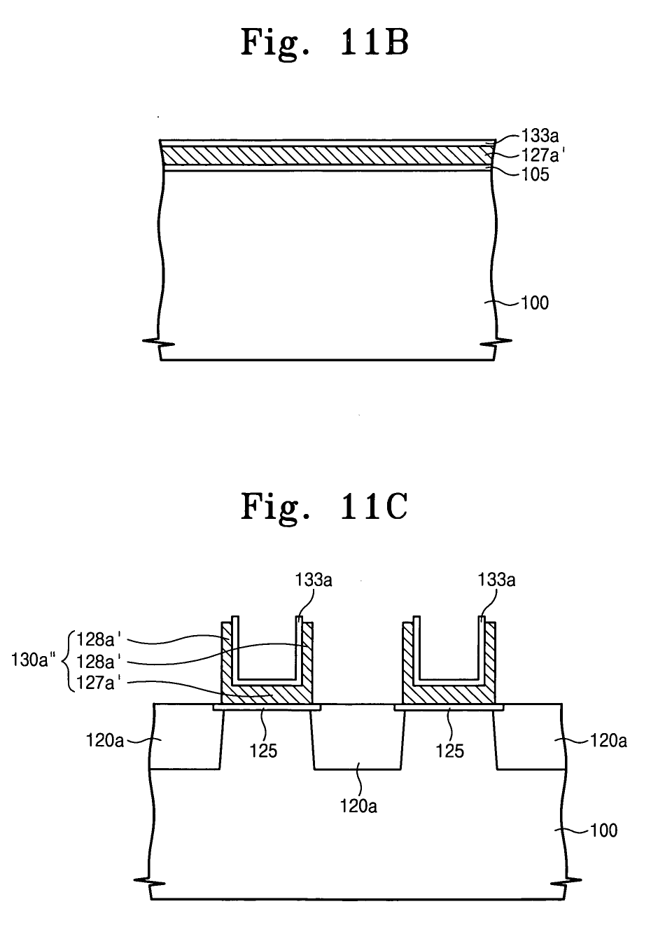

Referring to FIGS. 11A, 11B, and 11C, the preliminary floating gate 130a is isotropically etched. Accordingly, the thickness of the isotropically etched preliminary flat portion 127a′ is larger than the width of the isotropically etched preliminary wall portions 128a′.

In the isotropic etching process of the present exemplary embodiment, the preliminary wall portions 128 are etched through outer surfaces, and thus the width of isotropically etched preliminary wall portions 128a′ decreases. On the other hand, both lower and upper surfaces of the preliminary flat portion 127 are not exposed. Accordingly, the isotropically etched preliminary flat portion 127a′ can maintain the thickness of the preliminary flat portion 127. As a result, the thickness of the isotropically etched preliminary flat portion 127a′ is larger than the width of the isotropically etched preliminary wall portions 128a′.

The mold pattern is completely removed from the substrate having the isotropically etched preliminary floating gate 130a″ to expose the upper surface of the isotropically etched preliminary flat portion 127a′ and the inner surfaces of the isotropically etched preliminary wall portions 128a′.

Further processes may be performed through the same method as the method described with reference to FIGS. 7A, 7B, and 7C. That is, the blocking insulating layer and the control gate conductive layer are formed on the substrate having the preliminary floating gate 130a″ after completely removing the mold pattern. The control gate conductive layer, the blocking insulating layer, and the preliminary floating gate 130a″ are sequentially patterned to form the floating gate, the blocking insulation pattern, and the control gate electrode which are sequentially stacked. Next, the impurity-doped layer may be formed in the active region by injecting the impurity ions using the control gate electrode as a mask.

According to the modified example of the present exemplary embodiment, the preliminary flat portion 127a′ of the preliminary floating gate 130a″ is formed thicker. Accordingly, etching damage of the active regions at both sides of the control gate electrode can be minimized during the etching process for forming the control gate electrode, the blocking insulation pattern, and the floating gate.

Also, according to the modified example of the present exemplary embodiment, the aspect ratio of the space between the adjacent preliminary floating gates 130a″ interposing the device isolating layer 120a can be decreased.

### Second Exemplary Embodiment

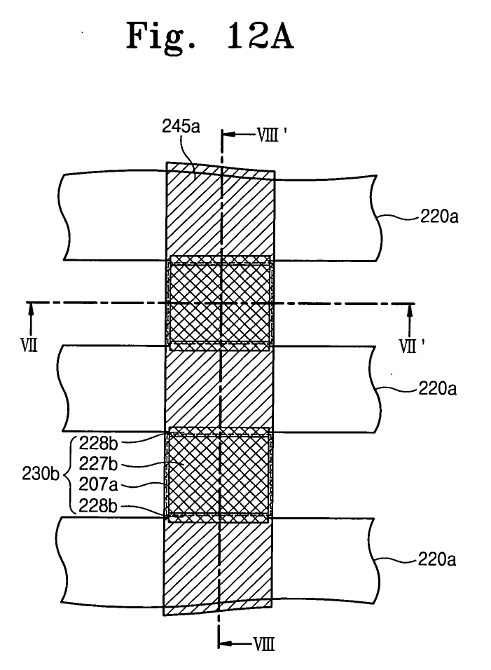

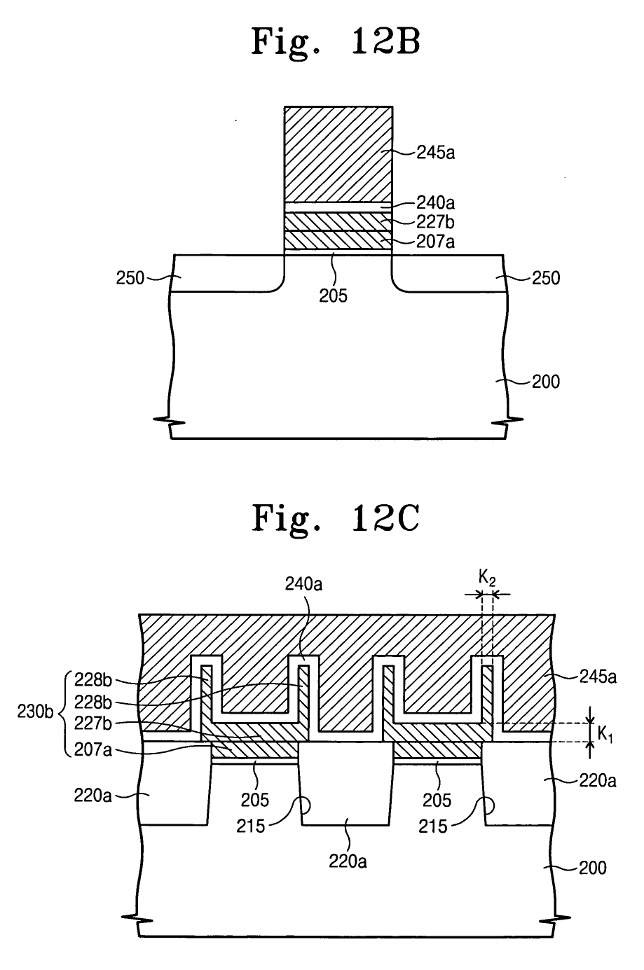

FIG. 12A is a plane view of a nonvolatile memory device according to an exemplary embodiment of the present invention, and FIGS. 12B and 12C are sectional views taken along the lines VII-VII and VIII-VIII′ of FIG. 12A respectively.

Referring to FIGS. 12A, 12B, and 12C, a device isolating layer 220a is disposed at a substrate 200 to define an active region, and a floating gate 230b is disposed on the active region. A tunnel insulating layer 205 is interposed between the floating gate 230b and the active region.

The floating gate 230b includes a buffer conductive pattern 207a, a flat portion 227b, and a pair of wall portions 228b. The buffer conductive pattern 207a is interposed between the flat portion 207b and the tunnel insulating layer 205, and the pair of wall portions 228b extend upward from both edges of the flat portion 227b and face each other. The wall portions 228b may, for example, extend upward from the edges of the flat portion 227b adjacent to the device isolating layer 220a. The buffer conductive pattern 207a electrically contacts the flat portion 227b. A thickness K1 of the flat portion 227b is larger than a width K2 of the wall portions 128b. The flat portion 227b and the wall portions 228b are formed of a single layer and are connected to each other.

The wall portions 228b may have, for example, a fin shape, and extend upward from the edges of the flat portion 227b adjacent to the device isolating layer 220a. The wall portions 228b have outer surfaces adjacent to the device isolating layer 220a and inner surfaces facing the outer surfaces. The edges of the flat portion 227b adjacent to the device isolating layer 220a may extend sideways to overlap a portion of the device isolating layer 220a. The buffer conductive pattern 207a is aligned with the width of the active region. The lower surface of the flat portion 227b may be larger than the upper surface of the buffer conductive pattern 207a.

An impurity-doped layer 250 is formed at the active regions at both sides of the floating gate 230b. The impurity-doped layer 250 corresponds to a source/drain region of a nonvolatile memory cell.

A control gate electrode 245a crossing the active regions is disposed on the floating gate 230b, and a blocking insulation pattern 240a is interposed between the control gate electrode 245a and the floating gate 230b.

The device isolating layer 220a may have a height such that the device isolating layer 220a is close to the lower surface of the flat portion 227b. Moreover, the upper surface of the device isolating layer 220a may have a height such that the upper surface of the device isolating layer 220a is close to the lower surface of the buffer conductive pattern 207a. The device isolating layer 220a may cover the tunnel insulating layer 205. The control gate electrode 245a covers the upper surface of the flat portion 227b and the inner surfaces of the wall portions 228b. The control gate electrode 245a may fill a space surrounded by the pair of wall portions 228b and the flat portion 227b, interposing the blocking insulation pattern 240a. Also, the control gate electrode 245a covers the outer surfaces of the wall portions 228b. In addition, the control gate electrode 245a may further cover a sidewall of the buffer conductive pattern 207a. A portion of the space adjacent to the impurity-doped layer 250 may be open. An upper portion of the space is open.

A side of the flat portion 227b, a side of the blocking insulation pattern 240a, and a side of the control gate electrode 245a are aligned with each other. The impurity-doped layers 250 are disposed at both sides of the floating gate 230b and the control gate electrode 245a.

The buffer conductive pattern 207a, the flat portion 227b, and the wall portions 228b may be formed of, for example, doped polysilicon. Here, for example, the buffer conductive pattern 207a may be formed of a first doped polysilicon, and the flat portion 227b and the wall portions 228b may be formed of a second doped polysilicon.

In the nonvolatile memory device of the exemplary embodiments of the present invention, the floating gate 230b has an increased surface area within an area limited by the wall portions 228b extending upward. Accordingly, the overlapping area of the floating gate 230b and the control gate electrode 245a increases, and thus the coupling ratio of the nonvolatile memory cell also increases. As a result, a nonvolatile memory device with lower power consumption and a high integration can be obtained.

As described above, the thickness K1 of the flat portion 227b is larger than the width K2 of the wall portions 228b. Also, the buffer conductive pattern 207a is interposed between the flat portion 227b and the tunnel insulating layer 205. Therefore, the bottom of the floating gate 230b becomes thicker. As a result, the active regions at both sides of the floating gate 230b and the control gate electrode 245a can be protected during an etching process for forming the control gate electrode 245a, the blocking insulation pattern 240a, and the floating gate 230b. That is, etching damage of the active regions at both sides of the control gate electrode 245a that may occur during the etching process can be minimized.

In addition, as the width of the wall portions 228b is small, the aspect ratio of the space between the pair of wall portions 228b and/or the aspect ratio of the space between the adjacent floating gates 230b interposing the device isolating layer 220a can be decreased. As a result, voids and the like can be prevented from being generated in the control gate electrode 245a to thereby prevent the nonvolatile memory device from being degenerated.

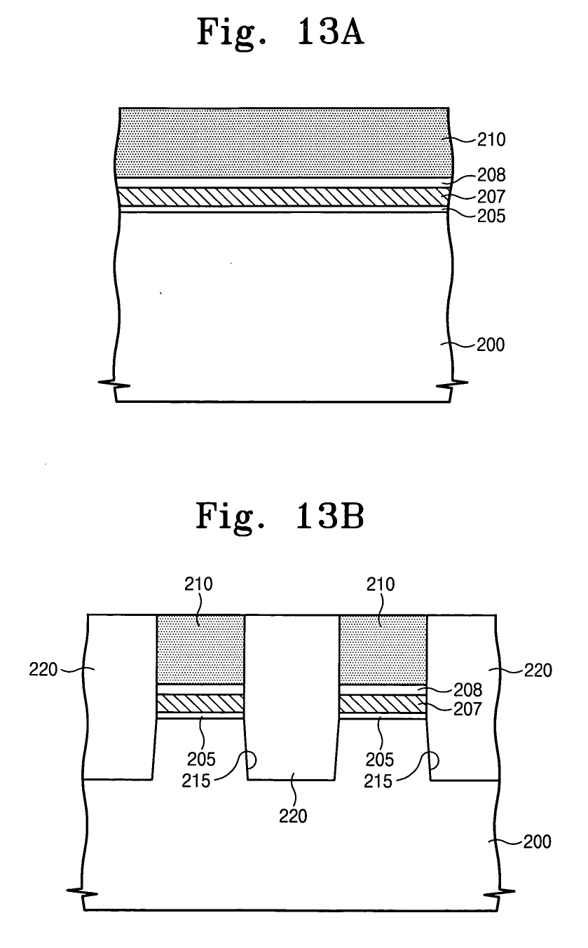

FIGS. 13A to 17A are sectional views taken along the line VII-VII′ of FIG. 12A for illustrating a method of forming a nonvolatile memory device according to an exemplary embodiment of the present invention, and FIGS. 13B to 17B are sectional views taken along the line VIII-VIII′ of FIG. 12A for illustrating a method of forming a nonvolatile memory device according to an exemplary embodiment of the present invention.

Referring to FIGS. 13A and 13B, a tunnel insulating layer 205, a preliminary buffer conductive pattern 207, and a hard mask pattern 210 are sequentially stacked on a predetermined region of a substrate 200. The tunnel insulating layer 205 may be formed of, for example, silicon oxide, such as a thermal oxidation layer. The preliminary buffer conductive pattern 207 may be formed of, for example, doped polysilicon. The hard mask pattern 210 is formed of material having an etching selectivity to the substrate 200. For example, the hard mask pattern 210 may be formed of nitride silicon or nitride oxide silicon. A protective insulating pattern 208 may be formed between the preliminary buffer conductive pattern 207 and the hard mask pattern 210. The protective insulating pattern 208 protects the preliminary buffer conductive pattern 207 from a stress (e.g., a tensile stress) of the hard mask pattern 210. For example, the protective insulating pattern 208 may be formed of silicon oxide.

Trenches 215 are formed by etching the substrate 200 using the hard mask pattern 210 as an etching mask to define an active region. An insulating layer is formed on the whole surface of the substrate 200 to fill the trenches 215, and the insulating layer is planarized until the hard mask pattern 210 is exposed to form a device isolating layer 220. The device isolating layer 220 may be formed of, for example, a silicon oxide layer formed through a high density plasma chemical vapor deposition (HDPCVD) process to have improved gap-fill properties.

Referring to FIGS. 14A and 14B, the exposed hard mask pattern 210 and the protective insulating pattern 208 are removed to expose the preliminary buffer conductive pattern 207 and form an empty space surrounded by a protruding portion of the device isolating layer 220 over the substrate 200. The hard mask pattern 210 may be removed, for example, through isotropic etching or anisotropic etching processes. The protective insulating pattern 208 may be removed, for example, by a wet etching process corresponding to an isotropic etching process. Accordingly, plasma etching damage can be prevented in the exposed preliminary buffer conductive pattern 207. As the protruding portion of the device isolating layer 220 is recessed by the wet etching process for removing the protective insulating pattern 208, the width of the empty space may be formed larger than the width of the active region. Also, as the preliminary buffer conductive pattern 207 is aligned with the active region, the width of the empty space may be formed larger than the width of the preliminary buffer conductive pattern 207. When the protective insulating pattern 208 is omitted, the wet etching process may be performed on the device isolating layer 220 after removing the hard mask pattern 210 to enlarge the width of the empty space.

A gate layer is formed on the substrate 200, and a sacrificial layer is formed on the gate layer. The gate layer is electrically connected to the exposed the preliminary buffer conductive pattern 207. The gate layer may be formed of, for example, a doped polysilicon layer. The sacrificial layer and the gate layer are planarized until the device isolating layer 220 is exposed. Accordingly, a preliminary flat portion 227 contacting the preliminary buffer conductive pattern 207, a pair of preliminary wall portions 228 extending upward from both edges of the preliminary flat portion 227, and a sacrifice pattern 235 covering an upper surface of the preliminary flat portion 227 and inner surfaces of the preliminary wall portions 228 are formed in the empty space. The preliminary flat portion 227 corresponds to a portion of the gate layer formed on the preliminary buffer conductive pattern 207, and the preliminary wall portions 228 correspond to a portion of the gate layer formed on sidewall portions of the empty space. A preliminary floating gate 230 includes the preliminary buffer conductive pattern 207, the preliminary flat portion 227, and the pair of preliminary wall portions 228.

The thickness of the preliminary flat portion 227 may be formed with the same thickness as the width of the preliminary wall portions 228. The preliminary wall portions 228 include outer surfaces adjacent to the device isolating layer 220 and inner surfaces adjacent to the sacrifice pattern 235.

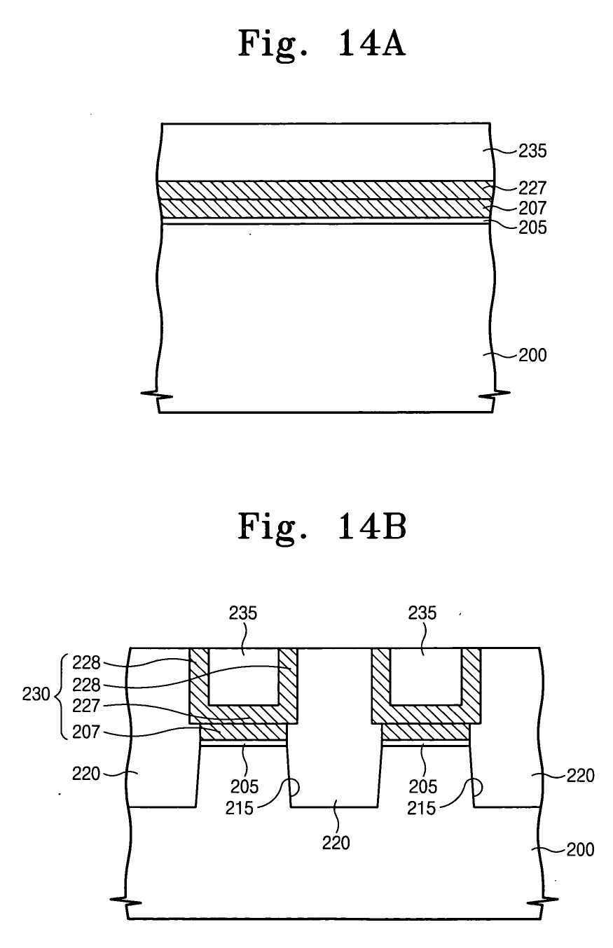

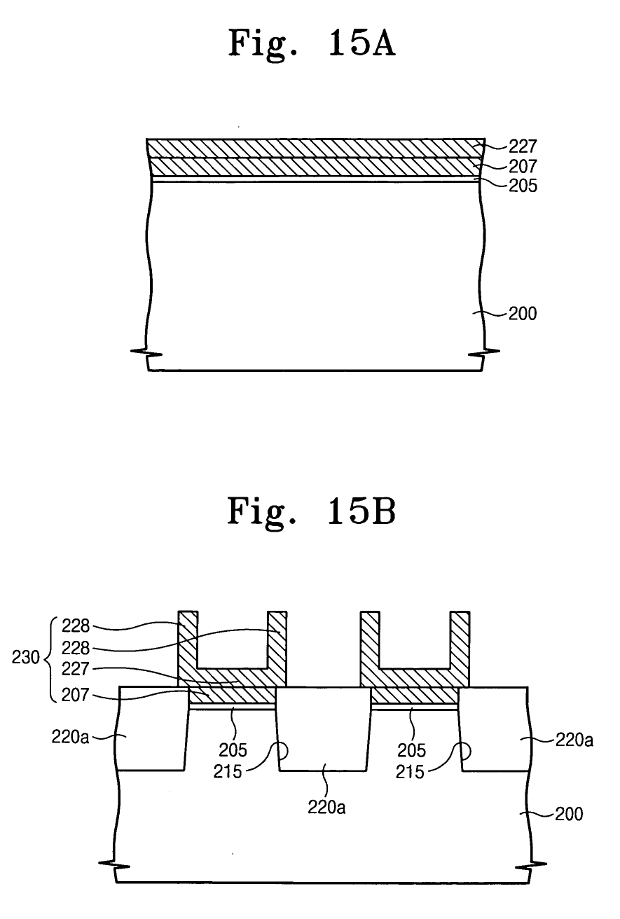

Referring to FIGS. 15A and 15B, the sacrifice pattern 235 is removed to expose the inner surfaces of the preliminary wall portions 228 and the upper surface of the preliminary flat portion 227. The device isolating layer 220 is recessed to expose the outer surfaces of the wall portions 228. The recessed device isolating layer 220a may have an upper surface that is close to a lower surface of the preliminary flat portion 227. Moreover, the recessed device isolating layer 220a may have a height that it is close to the lower surface of the preliminary buffer conductive pattern 207. In this case, a side of the preliminary buffer conductive pattern 207 may be exposed. The recessed device isolating layer 220a may cover, for example, a side of the tunnel insulating layer 205.

Both inner and outer surfaces of the preliminary wall portions 228 are exposed through the removing process of the sacrifice pattern 235 and the recessing process of the device isolating layer 220, whereas the upper surface of the preliminary flat portion 227 is exposed, and the lower surface of the preliminary flat portion 227 (particularly, a portion of the preliminary flat portion 228 to cover the active region) is not exposed.

As with the above-mentioned first exemplary embodiment, the device isolating layer 220 of the present exemplary embodiment may be recessed after removing the sacrifice pattern 235 or the sacrifice pattern 235 may be removed after recessing the device isolating layer 220. Alternatively, the removing process of the sacrifice pattern 235a may be performed at the same time as the recessing process of the device isolating layer 220. The sacrifice pattern 235 may be formed of, for example, oxide silicon, oxide nitride silicon, or a nitride silicon.

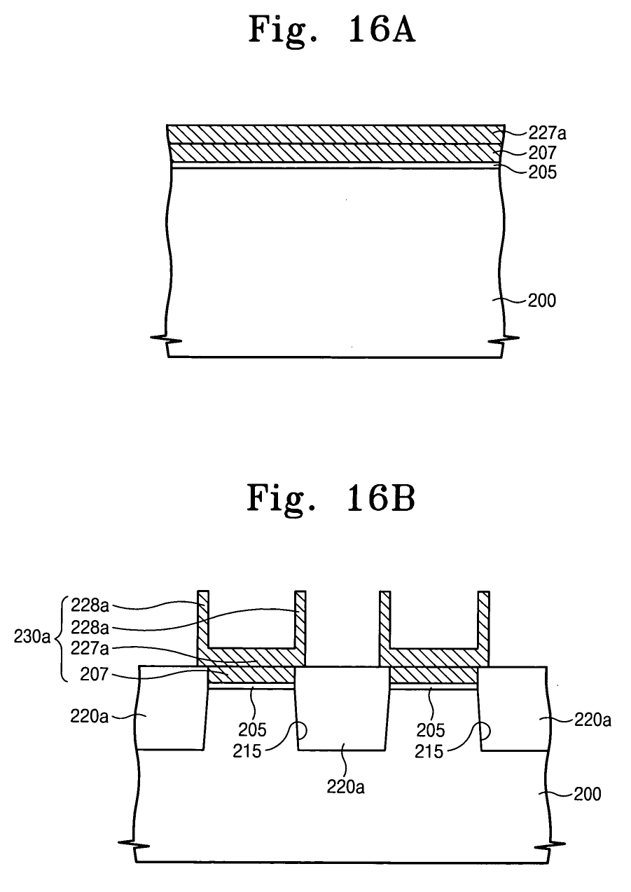

Referring to FIGS. 16A and 16B, the exposed preliminary floating gate 230 is isotropically etched. The isotropically etched preliminary flat portion 227a has a thickness that is larger than the width of the isotropically etched preliminary wall portions 228a. This is because, as described above, the upper surface of the preliminary flat portion 227 is exposed, while both inner and outer surfaces of the preliminary wall portions 228 are exposed. When the recessed device isolating layer 220a is formed at a height that is close to the lower surface of the preliminary buffer conductive pattern 207, a lower surface of an overlapping portion between the isotropically etched preliminary flat portion 227a and the recessed device isolating layer 220a may be etched. However, a portion of the isotropically etched preliminary flat portion 227a covering the active region is not exposed, and thus is formed to be thick. The upper and lower surfaces of the preliminary buffer conductive pattern 207 respectively contact the preliminary flat portion 227 and the tunnel insulating layer 205, and thus are not exposed. Accordingly, the thickness of the preliminary buffer conductive pattern 207 is maintained as is during the isotropic etching process.

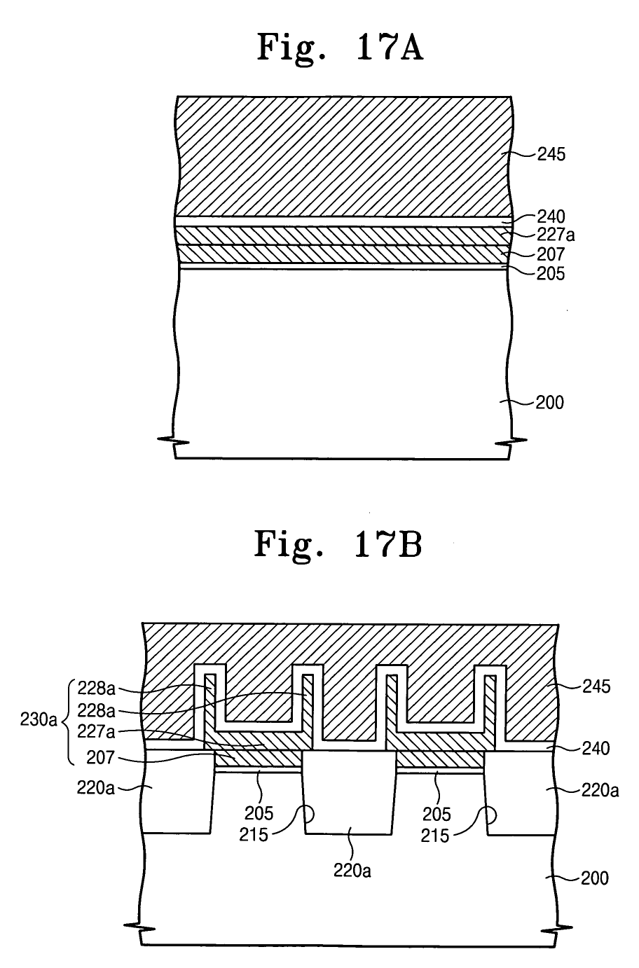

Referring to FIGS. 17A and 17B, a blocking insulating layer 240 is formed on the substrate 200 having the isotropically etched preliminary floating gate 230a, and a control gate conductive layer 240 is formed on the blocking insulating layer 240. The blocking insulating layer 240 may be formed of, for example, an oxide-nitride-oxide layer. Alternatively, the blocking insulating layer 240 may include a high dielectric layer having a higher dielectric constant than the tunnel insulating layer 205. For example, the blocking insulating layer 240 may include an insulating metal oxide layer such as a hafnium oxide layer or an aluminum oxide layer. The control gate conductive layer 245 may be formed of, for example, a single layer of a doped polysilicon layer, a metal layer (e.g., a tungsten layer or a molybdenum layer), a conductive metal nitride layer (e.g., a titanium nitride layer or a tantalum nitride layer), a metal silicide layer (e.g., a tungsten silicide layer, a cobalt silicide layer, a nickel silicide layer, or a titanium silicide layer) or a multilayer of the aforementioned layers.

When the height of the upper surface of the recessed device isolating layer 220a is close to the lower surface of the preliminary buffer conductive pattern 207, the blocking insulating layer 240 may cover a sidewall of the preliminary buffer conductive pattern 207.

The control gate conductive layer 245, the blocking insulating layer 240, and the isotropically etched preliminary floating gate 230a are sequentially patterned, forming the floating gate 230b, the blocking insulation pattern 240a, and the control gate electrode 245a, as illustrated in FIGS. 12A, 12B, and 12C.

A buffer conductive pattern 207a, a flat portion 227b, and wall portions 228b, which are included in the floating gate 230b, are respectively formed from the preliminary buffer conductive pattern 207, the isotropically etched preliminary flat portion 227a, and the isotropically etched preliminary wall portions 228a.

An impurity-doped layer 250 is formed, as illustrated in FIG. 12B, by injecting impurity ions using the control gate electrode 245a as a mask. Therefore, the nonvolatile memory device, as illustrated in FIGS. 12A, 2B, and 12C, can be implemented.

With the aforementioned method of forming the nonvolatile memory device in accordance with an exemplary embodiment of the present invention, the floating gate 230b includes the flat portion 227b and the pair of wall portions 228b extending upward from both edges of the flat portion 127b. Therefore, the surface area of the floating gate 230b increases in a limited area, thereby increasing the coupling ratio of the nonvolatile memory cell. As a result, a nonvolatile memory device with low power consumption and a high integration may be obtained.

Also, the thickness of the isotropically etched preliminary flat portion 227a is larger than the width of the isotropically etched preliminary wall portions 228a, and the preliminary buffer conductive pattern 207 is formed between the isotropically etched preliminary flat portion 227a and the tunnel insulating layer 205. Therefore, etching damage to the active region at both sides of the control gate electrode 245a which may occur during the etching process of the patterning process for forming the control gate electrode 245a and the floating gate 230b can be minimized due to the thickness of the preliminary flat portion 227a and the preliminary buffer conductive pattern 207. As a result, a nonvolatile memory device with an improved leakage current characteristic may be obtained.

In addition, as the width of the isotropically etched preliminary wall portions 228a is decreased, the aspect ratio of the space between the pair of preliminary wall portions 228a and/or the aspect ratio of the space between the adjacent preliminary floating gates 230a interposing the recessed device isolating layer 220a may be decreased. Accordingly, with the exemplary embodiments of the present invention, the generation of voids can be prevented during the process of forming the control gate conductive layer 245 in the spaces.

Meanwhile, another method of forming a preliminary flat portion thicker than the width of preliminary wall portions will now be described below with reference to drawings.

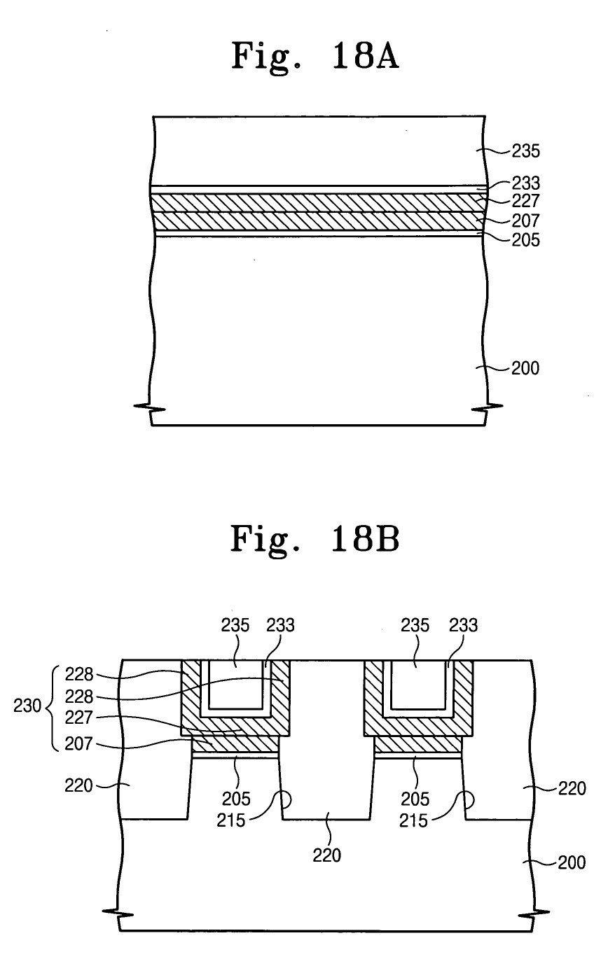

FIGS. 18A to 20A are sectional views taken along of the line VII-VII′ FIG. 12A for illustrating a modified example of a method of forming a nonvolatile memory device according to an exemplary embodiment of the present invention, and FIGS. 18B to 20B are sectional views taken along of the line VIII-VIII′ FIG. 12A for illustrating a modified example of a method of forming a nonvolatile memory device according to an exemplary embodiment of the present invention.

Referring to FIGS. 18A and 18B, a gate layer can be formed in an empty space surrounded by a protruding portion of the device isolating layer 220 using the same method as the method described with reference to FIGS. 13A, 13B, 14A, and 14B.

A mold layer is formed on the gate layer. The mold layer includes material having an etching selectivity to the device isolating layer 220. For example, the mold layer may include sequentially stacked capping layer and sacrificial layer. The capping layer is formed of material having an etching selectivity to the device isolating layer 220. The sacrificial layer may be formed of the same material as the device isolating layer 220. Alternatively, the sacrificial layer may be formed of material having an etching selectivity to the device isolating layer 220. That is, the whole mold layer may be formed of material having an etching selectivity to the device isolating layer 220.

The mold layer and the gate layer are planarized until the device isolating layer 220 is exposed to form a preliminary flat portion 227, a pair of preliminary wall portions 228, and a mold pattern in the empty space. The mold pattern covers inner surfaces of the pair of preliminary wall portions 228 and the upper surface of the preliminary flat portion 227. The mold pattern may include a capping pattern 233 and a sacrifice pattern 235 which are sequentially stacked. The capping pattern 233 may be formed of, for example, nitride silicon. The sacrifice pattern 235 may be formed of, for example, oxide silicon or nitride silicon.

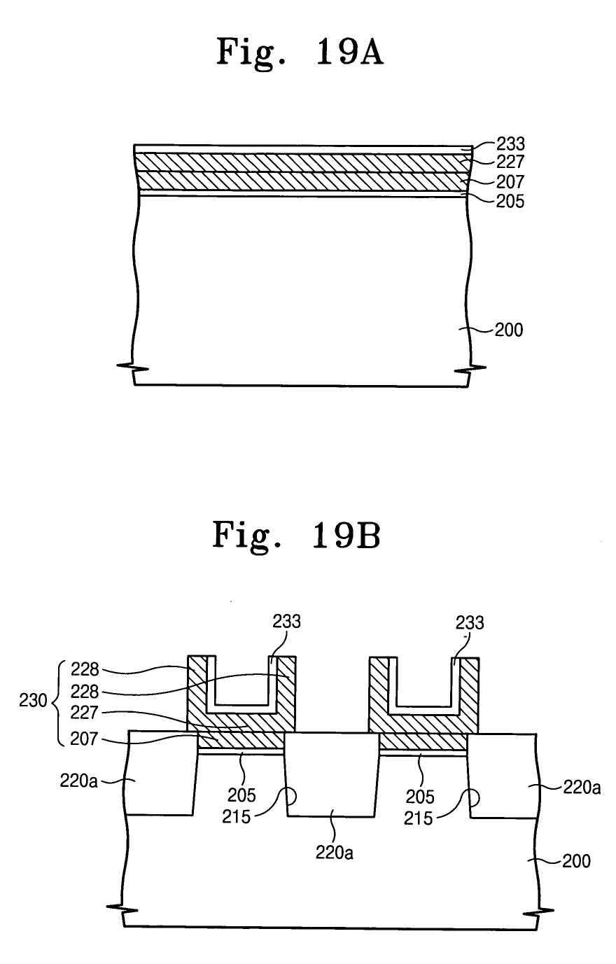

Referring to FIGS. 19A and 19B, the device isolating layer 220 is recessed to expose outer surfaces of the preliminary wall portions 228. At this point, at least a portion of the mold pattern remains to cover the inner surfaces of the preliminary wall portions 228 and the upper surface of the preliminary flat portion 227. The remaining portion of the mold pattern is a material having an etching selectivity to the device isolating layer 220. When the sacrifice pattern 235 is formed of the same material as the device isolating layer 220, the sacrifice pattern 235 may be removed, but the capping pattern 233 may remain during the recessing of the device isolating layer 220. When a whole mold pattern is formed of the same material as the device isolating layer 220, most of the mold pattern may remain.

As described above, the upper surface of the recessed device isolating layer 220 may have a height such that the upper surface of the recesses device isolating layer 220 is close to the lower surface of the preliminary flat portion 227 or to the lower surface of the preliminary buffer conductive pattern 207.

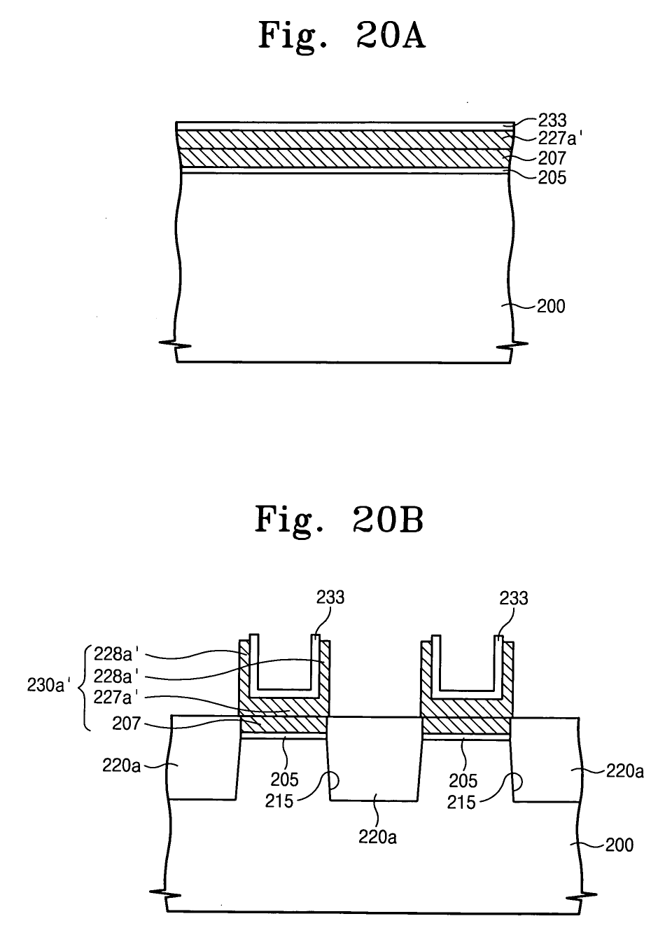

Referring to FIGS. 20A and 20B, the preliminary floating gate 230a is isotropically etched, wherein the outer surfaces of the preliminary wall portions 228 are exposed. Accordingly, the thickness of an isotropically etched preliminary flat portion 227a′ is larger than the width of an isotropically etched preliminary wall portions 228a′. Upper and lower surfaces of a portion of the preliminary flat portion 227 covering the active region and the inner surfaces of the preliminary wall portions 288 are not exposed during the isotropic etching process. Accordingly, the width of the preliminary wall portions 228 is decreased by the isotropic etching process, while a thickness of a portion of the preliminary flat portion 227 covering the active region is maintained as is. The thickness of the preliminary buffer conductive pattern 207 is also maintained as is. As a result, the thickness of the isotropically etched preliminary flat portion 227a′ is larger than the width of the isotropically etched preliminary wall portions 228a′.

Next, the mold pattern is completely removed to expose an upper surface of the isotropically etched preliminary flat portion 227a′ and inner surfaces of the isotropically etched preliminary wall portions 228a′. An isotropically etched preliminary floating gate 230a′ includes the isotropically etched preliminary flat portion 227a′, the pair of preliminary wall portions 228a′, and the preliminary buffer conductive pattern 207.

Further processes may be performed through the same method as the method described with reference to FIGS. 17A and 17B. That is, a blocking insulating layer and a control gate conductive layer are formed on the substrate having the preliminary floating gate 230a′ after completely removing the mold pattern. The control gate conductive layer, the blocking insulating layer, and the preliminary floating gate 230a′ are sequentially patterned to form a floating gate, a blocking insulation pattern, and a control gate electrode that are sequentially stacked. Next, an impurity-doped layer may be formed in the active region by injecting impurity ions using the control gate electrode as a mask.

According to the aforementioned modified example, the preliminary flat portion 227a′ of the preliminary floating gate 230a is formed thicker. Etching damage at the active region at both sides of the control gate electrode can be minimized by the preliminary flat portion 227a′ and the preliminary buffer conductive pattern 207 during the etching process for forming the control gate electrode, the blocking insulation pattern, and the floating gate. Also, according to the modified example, the aspect ratio of the space between the adjacent preliminary floating gates 230a′ interposing the device isolating layer 220a can be decreased.

According to exemplary embodiments of the present invention, the floating gate includes the flat portion and the pair of wall portions extending upward from both edges of the flat portion. Accordingly, the surface area of the floating gate can be increased in a limited area. As a result, the coupling ratio of the nonvolatile memory cell increases to provide a nonvolatile memory device with low power consumption and a high integration.

Also, the flat portion is formed thicker than the width of the wall portions. Accordingly, etching damage to the substrate at both sides of the floating gate can be minimized during the etching process for forming the floating gate.

Also, as the width of the wall portions is small, the aspect ratio of the space between the pair of wall portions and/or the aspect ratio of the space between the adjacent floating gates can be decreased. Accordingly, the generation of voids can be prevented in the spaces.

Also, the floating gate may further include the buffer conductive pattern interposed between the tunnel insulating layer and the flat portion. Accordingly, etching damage to the substrate at both sides of the floating gate can be further minimized.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A nonvolatile memory device comprising:
a device isolating layer disposed at a substrate to define an active region;
a floating gate disposed on the active region and including a flat portion and a pair of wall portions, the pair of wall portions extend upward from both edges of the flat portion adjacent to the device isolating layer and face each other; and
a tunnel insulating layer interposed between the floating gate and the active region,
wherein the wall portions and the flat portion are formed of a single layer, and a thickness of the flat portion is larger than a width of the wall portions.

2. The nonvolatile memory device of claim 1, further comprising:
a control gate electrode disposed on the floating gate and crossing the active region; and
a blocking insulation pattern interposed between the control gate electrode and the floating gate,
wherein the wall portions include outer surfaces adjacent to the device isolating layer and inner surfaces facing the outer surface, and the control gate electrode covers an upper surface of the flat portion located between the pair of wall portions and the inner surfaces of the wall portions.

3. The nonvolatile memory device of claim 2, wherein an upper surface of the device isolating layer is lower than an uppermost surface of the wall portions, and the control gate electrode covers the outer surfaces of the wall portions located above the upper surface of the device isolating layer while interposing the blocking insulation pattern.

4. The nonvolatile memory device of claim 1, wherein edges of the flat portion adjacent to the device isolating layer extend to cover edges of the device isolating layer.

5. The nonvolatile memory device of claim 1, wherein the floating gate further comprises a buffer conductive pattern interposed between the flat portion and the tunnel insulating layer to be electrically connected to the flat portion.

6. The nonvolatile memory device of claim 5, wherein a lower surface of the flat portion is larger than an upper surface of the buffer conductive pattern.

7. The nonvolatile memory device of claim 5, wherein the buffer conductive pattern comprises a side aligned to a side of the flat portion.

8. The nonvolatile memory device of claim 1, further comprising an impurity-doped layer formed at the active region at both sides of the floating gate.

9. A method of forming a nonvolatile memory device, the method comprising:
forming a device isolating layer disposed at a substrate to define an active region, and a tunnel insulating layer on the active region;
forming, on the tunnel insulating layer, a preliminary floating gate which includes a preliminary flat portion covering the active region and preliminary wall portions extending upward from both edges of the preliminary flat portion adjacent to the device isolating layer;
performing an isotropic etching process such that a thickness of the preliminary flat portion is larger than a width of the preliminary wall portions; and
forming a floating gate including a flat portion and a pair of wall portions extending upward from both edges of the flat portion by patterning the isotropically etched preliminary floating gate.

10. The method of claim 9, further comprising:
forming a blocking insulating layer on the substrate; and
forming a control gate conductive layer on the blocking insulating layer,
wherein the patterning of the isotropically etched preliminary floating gate includes patterning the control gate conductive layer, the blocking insulating layer, and the isotropically etched preliminary floating gate to form the floating gate, a blocking insulation pattern, and a control gate electrode.

11. The method of claim 9, wherein the isotropic etching is performed such that outer surfaces of the preliminary wall portions adjacent to the device isolating layer, inner surfaces of the preliminary wall portions facing the outer surfaces, and an upper surface of the preliminary flat portion located between the preliminary wall portions are exposed.

12. The method of claim 11, wherein the forming of the preliminary floating gate comprises:
forming an empty space surrounded by a protruding portion of the device isolating layer over the substrate to expose the tunnel insulating layer;
forming a gate layer and a sacrificial layer on the substrate;
forming the preliminary flat portion, the preliminary wall portions, and a sacrifice pattern in the empty space by planarizing the sacrificial layer and the gate layer until the device isolating layer is exposed;
exposing the inner surfaces of the preliminary wall portions and the upper surface of the preliminary flat portion between the preliminary wall portions by removing the sacrifice pattern; and
exposing the outer surfaces of the preliminary wall portions by recessing the device isolating layer.

13. The method of claim 11, further comprising forming of a preliminary buffer conductive pattern interposed between the tunnel insulating layer and the preliminary flat portion,
wherein the preliminary floating gate further includes the preliminary buffer conductive pattern, and the floating gate further includes a buffer conductive pattern formed by patterning the preliminary buffer conductive pattern.

14. The method of claim 13, wherein the forming of the preliminary floating gate comprises:
forming an empty space surrounded by a protruding portion of the device isolating layer over the substrate to expose the preliminary buffer conductive pattern;
forming a gate layer and a sacrificial layer on the substrate;
forming the preliminary flat portion, the preliminary wall portions, and a sacrifice pattern in the empty space by planarizing the sacrificial layer and the gate layer until the device isolating layer is exposed;
exposing the inner surfaces of the preliminary wall portions and the upper surface of the preliminary flat portion between the preliminary wall portions by removing the sacrifice pattern; and
exposing the outer surfaces of the preliminary wall portions by recessing the device isolating layer.

15. The method of claim 9, wherein the isotropic etching is performed such that outer surfaces of the preliminary wall portions adjacent to the device isolating layer is exposed, and inner surfaces of the preliminary wall portions facing the outer surfaces and an upper surface of the preliminary flat portion located between the preliminary wall portions are covered.

16. The method of claim 15, wherein the forming of the preliminary floating gate comprises:
forming an empty space surrounded by a protruding portion of the device isolating layer over the substrate to expose the tunnel insulating layer;
forming a gate layer and a mold layer on the substrate;
forming the preliminary flat portion, the preliminary wall portions, and a mold pattern in the empty space by planarizing the mold layer and the gate layer until the device isolating layer is exposed; and
exposing the outer surfaces of the preliminary wall portions by recessing the device isolating layer such that at least a portion of the mold pattern remains to cover the inner surfaces of the preliminary wall portions and the upper surface of the preliminary flat portion.

17. The method of claim 16, wherein the mold layer comprises a capping layer and a sacrificial layer, and the capping layer is formed of a material having an etching selectivity to the device isolating layer while the sacrificial layer is formed of the same material as the device isolating layer.

18. The method of claim 15, further comprising forming a preliminary buffer conductive pattern interposed between the tunnel insulating layer and the preliminary flat portion,
wherein the preliminary floating gate further includes the preliminary buffer conductive pattern, and the floating gate further includes a buffer conductive pattern formed by patterning the preliminary buffer conductive pattern.

19. The method of claim 18, wherein the forming of the preliminary floating gate comprises:
forming an empty space surrounded by a protruding portion of the device isolating layer over the substrate to expose the preliminary buffer conductive pattern;
forming a gate layer and a mold layer on the substrate;
forming the preliminary flat portion, the preliminary wall portions, and a mold pattern in the empty space by planarizing the mold layer and the gate layer until the device isolating layer is exposed; and
exposing the outer surfaces of the preliminary wall portions by recessing the device isolating layer such that at least a portion of the mold pattern remains to cover the inner surfaces of the preliminary wall portions and the upper surface of the preliminary flat portion.

20. The method of claim 19, wherein the mold layer includes a capping layer and a sacrificial layer, and the capping layer is formed of material having an etching selectivity to the device isolating layer while the sacrificial layer is formed of the same material as the device isolating layer.

21. The method of claim 16, further comprising completely removing the mold pattern after performing the isotropic etching process.

22. The method of claim 19, further comprising completely removing the mold pattern after performing the isotropic etching process.
